(19) United States
(12) Patent Application Publication
(10) Pub. No.: US 2026/0229285 A1
(43) Pub. Date: Aug. 6, 2026

(54) SEQUENCE FOR FIRST FIRE AND FORMING IN CROSS-POINT ARRAYS

(71) Applicant: Sandisk Technologies, Inc., Milpitas, CA (US)

(72) Inventors: Juan P. Saenz, Menlo Park, CA (US); Mark Lin, Santa Clara, CA (US); Mario Laudato, Santa Clara, CA (US); Kadriye Deniz Bozdag, Sunnyvale, CA (US); Dimitri Houssameddine, Sunnyvale, CA (US)

(73) Assignee: Sandisk Technologies, Inc., Milpitas, CA (US)

(21) Appl. No.: 19/046,314

(22) Filed: Feb. 5, 2025

(51) Int. Cl. G11C 13/00; G11C 11/16; H10B 61/00; H10B 63/00

(52) U.S. Cl. CPC G11C 13/0069; G11C 11/1675; H10B 61/10; H10B 63/24; H10B 63/80; G11C 2013/0083

(57) ABSTRACT

Technology for a system and method for performing forming operations for programmable resistance memory cells in a cross-point array. The forming operations may be performed during successive time periods on different groups of memory cells wherein each memory cell in each group is connected between a word line and a bit line that are not connected to any other memory cell in the group. The sequence in which the memory cells are selected for the forming operations substantially reduces the likelihood of undesirable “half-select” events. The programmable resistance memory cells may have threshold switching selectors.

### BACKGROUND

Memory is widely used in various electronic devices such as cellular telephones, digital cameras, personal digital assistants, medical electronics, mobile computing devices, non-mobile computing devices, and data servers. Memory may comprise non-volatile memory or volatile memory. A non-volatile memory allows information to be stored and retained even when the non-volatile memory is not connected to a source of power (e.g., a battery). Non-volatile memory can be made to appear non-volatile at least for a limited time by, external to the memory chip, adding battery back to the power supply.

The memory cells may reside in a cross-point memory array. In a memory array with a cross-point type architecture, one set of conductive lines run across the surface of a substrate and another set of conductive lines are formed above the other set of conductive lines running in an orthogonal direction relative to the initial layer. The memory cells are located at the cross-point junctions of the two sets of conductive lines. Cross-point memory arrays are sometimes referred to as cross-bar memory arrays.

The cross-point memory array may contain programmable resistance memory cells. A programmable resistance memory cell is formed from a material having a programmable resistance. In a binary approach, the programmable resistance memory cell can be programmed into one of two resistance states: high resistance state (HRS) and low resistance state (LRS). In some approaches, more than two resistance states may be used. A number of types of programmable resistance memory cells have been proposed. One type of programmable resistance memory cell is a magnetoresistive random access memory (MRAM) cell. An MRAM cell uses magnetization to represent stored data, in contrast to some other memory technologies that use electronic charges (DRAM) or voltages (SRAM) to store data. A bit of data is written to an MRAM cell by changing the direction of magnetization of a magnetic element (“the free layer”) within the MRAM cell, and a bit is read by measuring the resistance of the MRAM cell, such resistance changing with the direction of magnetization. However, the cross-point memory array may have other types of memory cells. For example, the cross-point memory array may have memory cell of other technologies such as ReRam, PCM (Phase Change Memory), or FeRam.

Some programmable resistance memory cells in a cross-point array have a threshold switching selector in series with the programmable resistance memory element. The threshold switching selector has a high resistance in an off or non-conductive state until it is biased to a voltage higher than its threshold voltage (Vth) or current above its threshold current, (It), and until its voltage bias falls below Vhold (“Voffset”) or current below a holding current Ihold. After the Vth is exceeded and while Vhold is exceeded across the threshold switching selector, the threshold switching selector has a significantly lower resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. To read a memory cell, the threshold switching selector is activated by being turned on before the resistance state of the memory cell is determined. One example of a threshold switching selector is an Ovonic Threshold Switch (OTS). Other examples of threshold switching selectors include, but are not limited to, Volatile Conductive Bridge (VCB), Metal-Insulator-Metal (MIM), or other material that provides a highly non-linear dependence of current on select voltage.

Selector only memory (SOM) cells have also been proposed for cross-point arrays. A SOM cell has a selector, such as an OTS, that also serves as the programmable resistance memory element. A SOM cell is sometimes referred to as a “self-selecting cell.”

Some types of programmable resistance memory cells in a cross-point memory array need, or at least benefit, from an operation to ready the memory cell for normal operation. A threshold switching selector may benefit from a forming operation to lower its initial threshold voltage (Vth) to a target Vth. When a threshold switching selector is turned on for the first time in the lifetime of the memory device, the Vth is substantially higher than during normal operations such as read or write. The voltage which is required to turn on the selector during the first use, referred to as a first-fire voltage, is substantially higher than the target voltage range which is required to turn on the selector during normal operation. This is due to a transformation which takes place to a threshold switching selector during a process referred to as “forming,” which lowers the Vth of the threshold switching selector. The state of the selector may be transformed from an initial amorphous state having an initial threshold voltage (Vinit) to an operating state having an operating threshold voltage (Vop) which is lower than the initial threshold voltage. The transformation results in a permanent decrease in the Vth of the selector. The transformation results in a structural change which may be due to thermal effects of the selector material.

A ReRAM cell is another type of programmable resistance memory cell that may benefit from an initial forming operation. The term “forming” may be used to describe putting the programmable resistance memory elements into a lower resistance state for the first time after fabrication. After a forming operation is performed, the programmable resistance memory elements may be “reset” to a high resistance state and then “set” again to a low resistance state. One theory that is used to explain the forming mechanism for ReRAM cells is that one or more conductive filaments are formed by the application of a voltage to the programmable resistance memory elements. One example of a programmable resistance memory element includes a metal oxide as the programmable (or reversible) resistance material. In response to a suitable voltage, a conductive filament may be formed in the metal oxide such that there is one or more conductive paths from the top electrode to the bottom electrode of the variable resistance memory element. The conductive filament lowers the resistance of the variable resistance memory element. Application of another voltage may rupture the conductive filaments, thereby increasing the resistance of the variable resistance memory element. Application of still another voltage may repair the rupture in the conductive filament, thereby decreasing the resistance of the programmable resistance memory element once again. The initial formation of the conductive filament may be referred to as “forming,” the rupture of the filament may be referred to as “resetting” and the repair of the rupture of the filament may be referred to as “setting”. The programmable resistance memory element may then be repeatedly switched between states by repeatedly resetting and setting the programmable resistance memory element. The resetting process puts the programmable resistance memory element in a high resistance state and the setting process puts the programmable resistance memory element in a low resistance state. Data values may then be assigned to the high resistance state and the low resistance state.

### BRIEF DESCRIPTION OF THE DRAWINGS

Like-numbered elements refer to common components in the different figures.

FIG. 1 is a block diagram of one embodiment of a non-volatile memory system connected to a host.

FIG. 2 is a block diagram of one embodiment of a memory die.

FIG. 3 is a block diagram of one embodiment of an integrated memory assembly containing a control die and a memory structure die.

FIG. 4A depicts one embodiment of a portion of a memory array that forms a cross-point architecture in an oblique view.

FIGS. 4B and 4C respectively present side and top views of the cross-point structure in FIG. 4A.

FIG. 4D depicts an embodiment of a portion of a two-level memory array that forms a cross-point architecture in an oblique view.

FIG. 5A illustrates an embodiment for the structure of an MRAM memory cell having a threshold switching selector.

FIG. 5B illustrates an embodiment for the structure of a selector only memory cell.

FIGS. 6A and 6B illustrate embodiments for the incorporation of threshold switching selectors into an MRAM memory array having a cross-point architecture.

FIG. 7 depicts an embodiment of a memory array having a cross-point architecture with a selected cell, half-selected cells, and full unselected cells.

FIG. 8 depicts example Vth distributions for memory cells.

FIG. 9A depicts an example cross-point array that will be referred to in order to discuss issues with performing forming operations on the memory cells.

FIG. 9B depicts the example cross-point array of FIG. 9A in which memory cell 401b is presently selected for a forming operation.

FIG. 9C depicts the example cross-point array of FIG. 9A in which memory cell 401c is the second memory cell selected for forming.

FIGS. 10A, 10B, 10C, 10D, 10E, 10F, 10G, and 10H depict a sequence of an embodiment of performing forming operations in a cross-point array.

FIG. 11 is a flowchart of one embodiment of a process of performing forming operations in a cross-point array.

FIG. 12 is a flowchart of an embodiment of a process of performing forming operations in a cross-point memory array.

### DETAILED DESCRIPTION

Technology is disclosed for a system and method for performing forming operations for programmable resistance memory cells in a cross-point array. The forming operations may be performed during successive time periods on different groups of memory cells wherein each memory cell in each group is connected between a word line and a bit line that are not connected to any other memory cell in the group. For example, forming operations may be performed during a first time period on a first group of memory cells wherein each memory cell in the first group is connected between a word line and a bit line that are not connected to any other memory cell in the first group. Then, during a second time period the forming operations may be performed on a second group of memory cells wherein each memory cell in the second group is connected between a word line and a bit line that are not connected to any other memory cell in the second group. This process may be then repeated during other time periods for other groups of memory cells. The sequence in which the memory cells are selected for the forming operations substantially reduces the likelihood of undesirable “half-select” events. A half-select may occur to a memory cell that has about ½ of the forming voltage applied across it. The programmable resistance memory cells may have threshold switching selectors such as an OTS. In an embodiment, forming operations are performed in a cross-point array for memory cells having a threshold switching selector in series with a programmable resistance memory element. In an embodiment, forming operations are performed for SOM cells in a cross-point array. In an embodiment, forming operations are performed for ReRAM cells in a cross-point array.

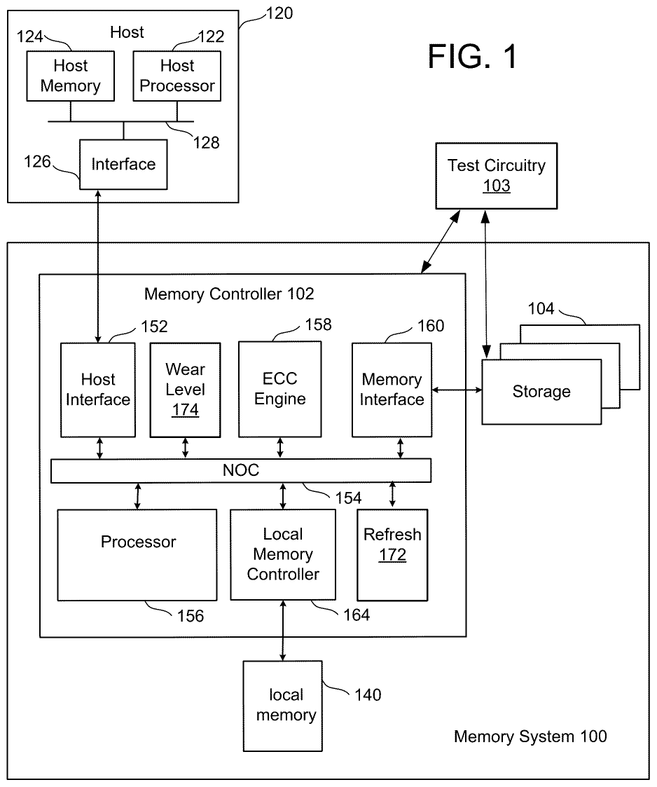

FIG. 1 is a block diagram of one embodiment of a non-volatile memory system (or more briefly “memory system”) 100 connected to a host system 120. Memory system 100 can implement the technology presented herein for performing forming operations for programmable resistance memory cells in a cross-point array. In an embodiment, the memory cells have a programmable resistance memory element (e.g., MRAM element) in series with a threshold switching selector such as an OTS. In an embodiment, the memory cells are “selector only memory cells” in which the threshold switching selector serves as both a selector and the programmable resistance memory element. In an embodiment, the memory cells are ReRAM cells. Many types of memory systems can be used with the technology proposed herein. Example memory systems include dual in-line memory modules (DIMMs), solid state drives (“SSDs”), memory cards and embedded memory devices; however, other types of memory systems can also be used.

Memory system 100 of FIG. 1 comprises a memory controller 102, memory 104 for storing data, and local memory 140 (e.g., MRAM, ReRAM, DRAM). The local memory 140 may be non-volatile and retain data after power off. The local memory 140 may be volatile and not be expected to retain data after power off. In one embodiment the local memory 140 is MRAM. In an embodiment, the local memory MRAM is not required to retain data after power-off. However, the local memory MRAM may retain data after power-off. In one embodiment, memory controller 102 and/or local memory controller 164 provides access to programmable resistance memory cells in local memory 140. For example, memory controller 102 may provide for access in a cross-point array of MRAM cells in local memory 140. In another embodiment the memory controller 102 or interface 126 or both are eliminated and the memory packages are connected directly to the host 120 through a bus such as DDRn. Or they are connected to a host memory management unit (MMU). In another instance, the memory controller 102 or portions are moved onto the memory 104 for direct connection of the memory 104 to the host, such as by providing parity bits, ECC, and wear level on the memory 104 along with an DDRn interface to/from the host 120 or MMU. The term memory system, as used throughout this document, is not limited to memory system 100. For example, the local memory 140 or the combination of local memory 140 and local memory controller 164 could be considered to be a memory system. Likewise, host memory 124 or the combination of host processor 122 and host memory 124 considered to be a memory system.

The components of memory system 100 depicted in FIG. 1 are electrical circuits. The memory controller 102 has host interface 152, processor 156, ECC engine 158, memory interface 160, local memory controller 164, refresh logic 172, and wear level 174. The host interface 152 is connected to and in communication with host 120. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, local memory controller 164, refresh logic 172, and wear level 174. Local memory controller 164 is used to operate and communicate with local high speed memory 140 (e.g., MRAM). In other embodiments, local high speed memory 140 can be DRAM, SRAM or another type of volatile memory.

ECC engine 158 performs error correction services. For example, ECC engine 158 performs data encoding and decoding of parity bits provided on or off the memory as part of the code word used for error correction of the data fetched from memory 140 or 104. In one embodiment, ECC engine 158 is an electrical circuit programmed by software. For example, ECC engine 158 can be a processor that can be programmed. In other embodiments, ECC engine 158 is a custom and dedicated hardware circuit without any software. In one embodiment, the function of ECC engine 158 is implemented by processor 156. In one embodiment, local memory 140 has an ECC engine with or without a wear level engine. In one embodiment, memory 104 has an ECC engine with or without a wear level engine.

Processor 156 performs the various controller memory operations, such as programming, erasing, reading, and memory management processes including wear level. A separate wear level 174 is depicted, but the wear level 174 may be implemented by processor 156. Also, refresh logic 172 is depicted, but the refresh may also be implemented by the processor 156. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory dies. To implement this system, memory controller 102 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in memory 104 and a subset of the L2P tables are cached (L2P cache) in the local high speed memory 140.

Memory interface 160 communicates with storage 104. In an embodiment, storage 104 contains programmable resistance memory cells in a cross-point array. In an embodiment, storage 104 contains NAND memory cells. In one embodiment, memory interface provides a Toggle Mode interface. Other interfaces can also be used. In some example implementations, memory interface 160 (or another portion of controller 102) implements a scheduler and buffer for transmitting data to and receiving data from one or more memory die.

In one embodiment, local memory 140 has an ECC engine. Local memory 140 may be used to help perform other functions such as wear leveling. Further details of on-chip memory maintenance are described in U.S. Pat. No. 10,545,692, titled “Memory Maintenance Operations During Refresh Window”, and U.S. Pat. No. 10,885,991, titled “Data Rewrite During Refresh Window”, both of which are hereby incorporated by reference in their entirety. In an embodiment, the local memory 140 is synchronous. In an embodiment, the local memory 140 is asynchronous.

In one embodiment, storage 104 comprises a plurality of memory packages. Each memory package includes one or more memory dies. Therefore, memory controller 102 is connected to one or more memory dies. In one embodiment, the memory package can include types of memory, such as storage class memory (SCM) based on programmable resistance random access memory (such as ReRAM, MRAM, FeRAM or RRAM) or a phase change memory (PCM). In one embodiment, memory controller 102 provides access to memory cells in a cross-point array in a storage 104.

Memory controller 102 communicates with host 120 via an interface 152 that implements a protocol such as, for example, Compute Express Link (CXL). Or such controller can be eliminated and the memory packages can be placed directly on the host bus, DDRn or CXL for examples. For working with memory system 100, host system 120 includes a host processor 122, host memory 124, and interface 126 connected along bus 128. Host memory 124 is the host's physical memory, and can be DRAM, SRAM, ReRAM, MRAM, non-volatile memory, or another type of storage. In an embodiment, host memory 124 contains a cross-point array of programmable resistance memory cells, with each memory cell comprising a programmable resistance memory element and a threshold switching selector in series with the programmable resistance memory element.

Host 120 is external to and separate from memory system 100. In one embodiment, memory system 100 is embedded in host 120. Host memory 124 may be referred to herein as a memory system. The combination of the host processor 122 and host memory 124 may be referred to herein as a memory system. In an embodiment, such host memory can be cross-point memory using MRAM.

In some embodiments, test circuitry 103 may be connected to storage 104 and/or memory controller 102 to facilitate tests of the storage 104. In some embodiments, test circuitry 103 may be used prior to shipping the memory system 100 and/or storage 104 to a customer. For example, test circuitry 103 could be used at a fabrication facility or a test facility. In some embodiments, test circuitry 103 controls a sequence of forming operations in the storage 104 as described herein. In some embodiments, memory controller 102 controls a sequence of forming operations in the storage 104 as described herein. The test circuitry 103 may implemented in hardware, software, or a combination of hardware and software.

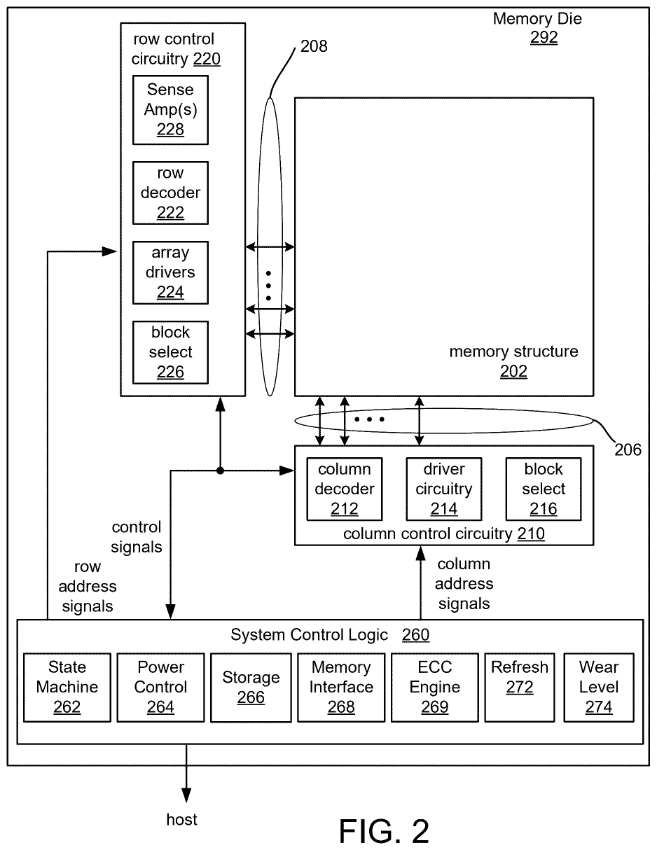

FIG. 2 is a block diagram that depicts one example of a memory die 292 that can implement the technology described herein. In one embodiment, memory die 292 is included in local memory 140, and in embodiment memory die 292 is included in storage 104. In one embodiment, memory die 292 is included in host memory 124. Memory die 292 includes a memory structure 202 that can include any of memory cells described in the following. The memory structure 202 may include one or more memory arrays. The array terminal lines of memory structure 202 include the various layer(s) of word lines organized as rows, and the various layer(s) of bit lines organized as columns. However, other orientations can also be implemented, including for example diagonal patterns to save space. Memory die 292 includes row control circuitry 220, whose outputs 208 are connected to respective word lines of the memory structure 202. Row control circuitry 220 receives a group of M row address signals and one or more various control signals from System Control Logic circuit 260, and typically may include such circuits as row decoders 222, row drivers 224, and block select circuitry 226 for both reading and writing operations. Row control circuitry 220 may also include read/write circuitry. In an embodiment, row control circuitry 220 has sense amplifiers 228, which each contain circuitry for sensing a condition (e.g., voltage) of a word line of the memory structure 202. In an embodiment, by sensing a word line voltage, a condition or bit state of a memory cell in a cross-point array is determined, either directly by a sense amp comparing the accessed memory cell voltage with a reference voltage. Or less directly by first accessing the memory cell and storing a read voltage generated by forcing a read current through the cell and adjusting it up or down by 150 mv (or half the voltage difference resulting from changing the bit state), then writing the cell to AP state, and again accessing the memory cell with a read current and comparing the resulting voltage with the stored voltage adjusted 150 mV for example (or half the difference in voltage resulting from two different bit states. Memory die 292 also includes column decoder and control circuitry 210 whose input/outputs 206 are connected to respective bit lines of the memory structure 202. Although only a single block is shown for memory structure 202, a memory die can include multiple arrays or “tiles” that can be individually accessed. Column control circuitry 210 receives a group of N column address signals and one or more various control signals from System Control Logic 260, and typically may include such circuits as column decoders 212, column decoders and drivers 214, block select circuitry 216, as well as read/write circuitry, and I/O multiplexers.

System control logic 260 receives data and commands from a host system and provides output data and status to the host system. In other embodiments, system control logic 260 receives data and commands from a separate controller circuit and provides output data to that controller circuit, with the controller circuit communicating with the host system. Such controller system may implement an interface such as DDR, DIMM, CXL, PCIe and others. In another embodiment those data and commands are sent and received directly from the memory packages to the Host without a separate controller, and any controller needed is within each die or within a die added to a multi-chip memory package. In some embodiments, the system control logic 260 can include a state machine 262 that provides die-level control of memory operations. In some embodiments, state machine 262 controls a sequence of forming operations in the storage 104 as described herein. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor. The system control logic 260 can also include a power control module 264 that controls the power, current source currents, and voltages supplied to the rows and columns of the memory structure 202 during memory operations and may include charge pumps and regulator circuit for creating regulating voltages, and on/off control of each for word line bit line selection of the memory cells. In some embodiments, the power control 264 includes one or more current sources. The current source(s) may be used to provide read and/or write currents. System control logic 260 includes storage 266, which may be used to store parameters for operating the memory structure 202. System control logic 260 also includes refresh logic 272 and wear leveling logic 274. Such system control logic may be commanded by the host 120 or memory controller 102 to refresh logic 272, which may load an on-chip stored row and column address (pointer) which may be incremented after refresh. Such address bit(s) may be selected only (to refresh the OTS). Or such address may be read, corrected by steering through ECC engine 269, and then stored in a “spare” location, which is also being incremented (so all codewords are periodically read, corrected, and relocated in the entire chip under control of wear leveling logic 274) to in effect wear level so use of each bit across the chip is more uniform. Such operation may be more directly controlled by the host of an external controller, for example a PCIe or CXL or DDRn controller located separately from the memory chip or on the memory die.

Commands and data are transferred between memory controller 102 and the memory die 292 via memory controller interface 268 (also referred to as a “communication interface”). Such interface may be PCIe, CXL, DDRn for example. Memory controller interface 268 is an electrical interface for communicating with memory controller 102. Examples of memory controller interface 268 also include a Toggle Mode Interface. Other I/O interfaces can also be used. For example, memory controller interface 268 may implement a Toggle Mode Interface that connects to the Toggle Mode interfaces of memory interface 228/258 for memory controller 102. In one embodiment, memory controller interface 268 includes a set of input and/or output (I/O) pins that connect to the controller 102. In another embodiment, the interface is JEDEC standard DDRn or LPDDRn, such as DDR5 or LPDDR5, or a subset thereof with smaller page and/or relaxed timing.

System control logic 260 located in a controller on the memory die in the memory packages may include Error Correction Code (ECC) engine 269. ECC engine 269 may be referred to as an on-die ECC engine, as it is on the same semiconductor die as the memory cells. That is, the on-die ECC engine 269 may be used to encode data and parity bits that are to be stored in the memory structure 202, and to decode the decoded data and correct errors. The encoded data may be referred to herein as a codeword or as an ECC codeword. ECC engine 269 may be used to perform a decoding algorithm and to perform error correction. Hence, the ECC engine 269 may decode the ECC codeword. In an embodiment, the ECC engine 269 is able to decode the data more rapidly by direct decoding without iteration. Having the ECC engine 269 on the same die as the memory cells allows for faster decoding. The ECC engine 269 can use a wide variety of decoding algorithms including, but not limited to, Reed Solomon, a Bose-Chaudhuri-Hocquenghem (BCH), and low-density parity check (LDPC).

In some embodiments, all of the elements of memory die 292, including the system control logic 260, can be formed as part of a single die. In other embodiments, some or all of the system control logic 260 can be formed on a different die; e.g., external controller chip.

In one embodiment, memory structure 202 comprises a three-dimensional memory array of non-volatile or volatile memory cells in which multiple memory levels are formed above a single substrate, such as a wafer. The memory structure may comprise any type of non-volatile or volatile memory that are monolithically formed in one or more physical levels of memory cells having an active area disposed above a silicon or silicon on insulator (or other type of) substrate. In another embodiment, memory structure 202 comprises a two-dimensional memory array of non-volatile memory cells.

The exact type of memory array architecture or memory cell included in memory structure 202 is not limited to the examples above. Many different types of memory array architectures or memory technologies can be used to form memory structure 202. No particular non-volatile memory technology is required for purposes of the newly claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM or MRAM cross-point memory includes programmable resistance switching elements in series with an OTS selector arranged in cross-point arrays accessed by X lines and Y lines (e.g., word lines and bit lines). In another embodiment of cross-point is PCM in series with an OTS selector. In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive random access memory (MRAM) stores data using magnetic storage elements. The elements are formed from two ferromagnetic layers, each of which can hold a magnetization, separated by a thin insulating layer. For a field-controlled MRAM, one of the two layers is a permanent magnet set to a particular polarity; the other layer's magnetization can be changed by applying an external field to store memory. Other types of MRAM cells are possible. A memory device may be built from a grid of MRAM cells or as SOT magneto resistive memory. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). The memory cells are programmed by current pulses that can change the co-ordination of the PCM material or switch it between amorphous and crystalline states. Note that the use of “pulse” in this document does not require a square pulse but includes a (continuous or non-continuous) vibration or burst of sound, current, voltage, light, or other wave. And the current forced for a write can, for example, be driven rapidly to a peak value and then linearly ramped lower with, for example, a 500ns edge rate. Such peak current force may be limited by a zoned voltage compliance that varies by position of the memory cell along the word line or bit line. In an embodiment, a phase change memory cell has a phase change memory element in series with a threshold switching selector such as an OTS.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2 can be grouped into two parts, the memory structure 202 and the peripheral circuitry, including all of the other elements. An important characteristic of a memory circuit is its capacity, which can be increased by increasing the area of the memory die 292 that is given over to the memory structure 202; however, this reduces the area of the memory die available for the peripheral circuitry or increases cost which is related to chip area. This can place quite severe restrictions on these peripheral elements. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die 292 is the amount of area to devote to the memory structure 202 and the amount of area to devote to the peripheral circuitry. Such tradeoffs may result in more IR drop from use of larger x-y arrays of memory between driving circuits on the word line and bit line, which in turn may benefit more from use of voltage limit and zoning of the voltage compliance by memory cell position along the word line and bit line.

Another area in which the memory structure 202 and the peripheral circuitry are often at odds is in the processing involved in forming these regions, since these regions often involve differing processing technologies and the trade-off in having differing technologies on a single die. For example, elements such as sense amplifier circuits, charge pumps, logic elements in a state machine, and other peripheral circuitry in system control logic 260 often employ PMOS devices. In some cases, the memory structure will be based on CMOS devices. Processing operations for manufacturing a CMOS die will differ in many aspects from the processing operations optimized for NMOS-only technologies.

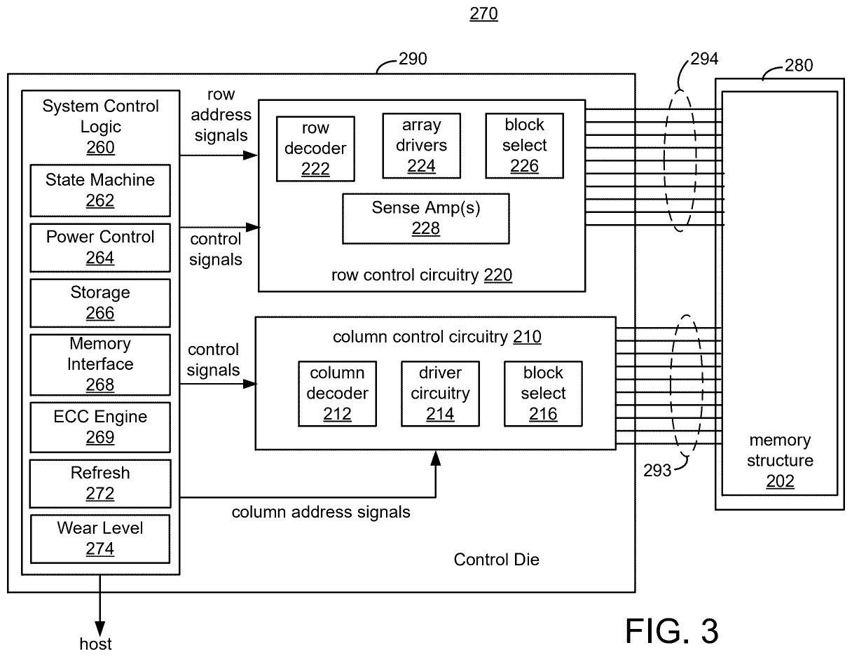

To improve upon these limitations, embodiments described below can separate the elements of FIG. 2 onto separately formed die that are then bonded together. FIG. 3 depicts an integrated memory assembly 270 having a memory structure die 280 and a control die 290. The memory structure 202 is formed on the memory structure die 280 and some or all of the peripheral circuitry elements, including one or more control circuits, are formed on the control die 290. For example, a memory structure die 280 can be formed of just the memory elements, such as the array of memory cells of MRAM memory, PCM memory, ReRAM memory, or other memory type. Some or all of the peripheral circuitry, even including elements such as decoders, current sources, and sense amplifiers, can then be moved on to the control die. This allows each of the semiconductor die to be optimized individually according to its technology. This allows more space for the peripheral elements, which can now incorporate additional capabilities that could not be readily incorporated were they restricted to the margins of the same die holding the memory cell array. The two die can then be bonded together in a bonded multi-die integrated memory assembly, with the array on the one die connected to the periphery elements on the other die. Although the following will focus on an integrated memory assembly of one memory die and one control die, other embodiments can use additional die, such as two memory die and one control die, for example.

As with memory die 292 of FIG. 2, the memory structure die 280 in FIG. 3 includes a memory structure 202 that can include multiple independently accessible arrays or “tiles.” System control logic 260, row control circuitry 220, and column control circuitry 210 are located in control die 290. In some embodiments, all or a portion of the column control circuitry 210 and all or a portion of the row control circuitry 220 are located on the memory structure die 280. In some embodiments, some of the circuitry in the system control logic 260 is located on the on the memory structure die 280.

FIG. 3 shows column control circuitry 210 on the control die 290 coupled to memory structure 202 on the memory structure die 280 through electrical paths 293. For example, electrical paths 293 may provide electrical connection between column decoder 212, column driver circuitry 214, and block select 216 and bit lines of memory structure 202. Electrical paths may extend from column control circuitry 210 in control die 290 through pads on control die 290 that are bonded to corresponding pads of the memory structure die 280, which are connected to bit lines of memory structure 202. Each bit line of memory structure 202 may have a corresponding electrical path in electrical paths 293, including a pair of bond pads, which connects to column control circuitry 210. Similarly, row control circuitry 220, including row decoder 222, row drivers 224, block select 226, and sense amplifiers 228 are coupled to memory structure 202 through electrical paths 294. Each of electrical path 294 may correspond to, for example, a word line. Additional electrical paths may also be provided between control die 290 and memory structure die 280.

For purposes of this document, the phrase “a control circuit” can include one or more of test circuitry 103, memory controller 102, local memory controller 164, processor 156, system control logic 260, column control circuitry 210, row control circuitry 220, host processor 122, a micro-controller, a state machine, and/or other control circuitry, or other analogous circuits that are used to control non-volatile memory. The control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit. Such control circuitry may include drivers such as direct drive via connection of a node through fully on transistors (gate to the power supply) driving to a fixed voltage such as a power supply. Such control circuitry may include a current source driver.

For purposes of this document, the term “apparatus” can include, but is not limited to, one or more of memory system 100, local memory 140, the combination of local memory controller 164 and/or memory controller 102 and local memory 140, storage 104, the combination of test circuitry 103 and storage 104, the combination of test circuitry 103 and memory system 100. memory die 292, integrated memory assembly 270, and/or control die 290.

In the following discussion, the memory structure 202 of FIGS. 2 and 3 will be discussed in the context of a cross-point architecture. In a cross-point architecture, a first set of conductive lines or wires, such as word lines, run in a first direction relative to the underlying substrate and a second set of conductive lines or wires, such a bit lines, run in a second direction relative to the underlying substrate. The memory cells are sited at the intersection of the word lines and bit lines. The memory cells at these cross-points can be formed according to any of a number of technologies, including those described above. The following discussion will mainly focus on embodiments based on a cross-point architecture having memory cells using a threshold switching selector such as Ovonic Threshold Switch (OTS). However, embodiments are not limited to a cross-point architecture having memory cells using an OTS. For example, the cross-point memory array may have memory cell of other technologies such as ReRam, PCM (Phase Change Memory), or FeRam.

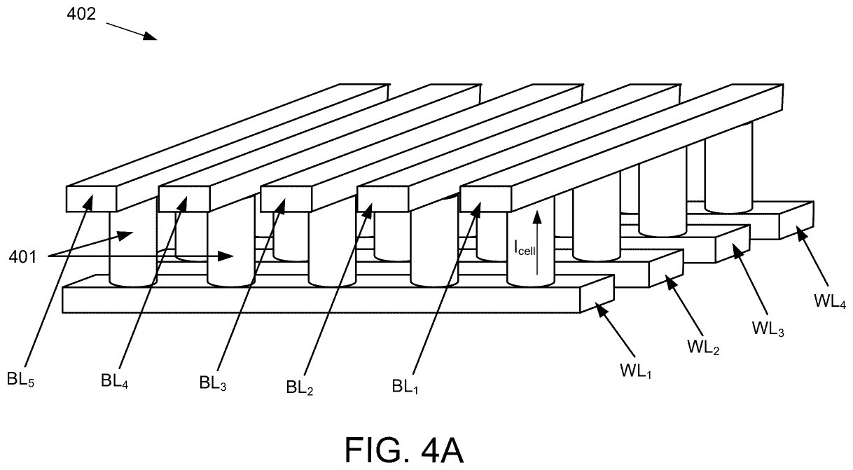

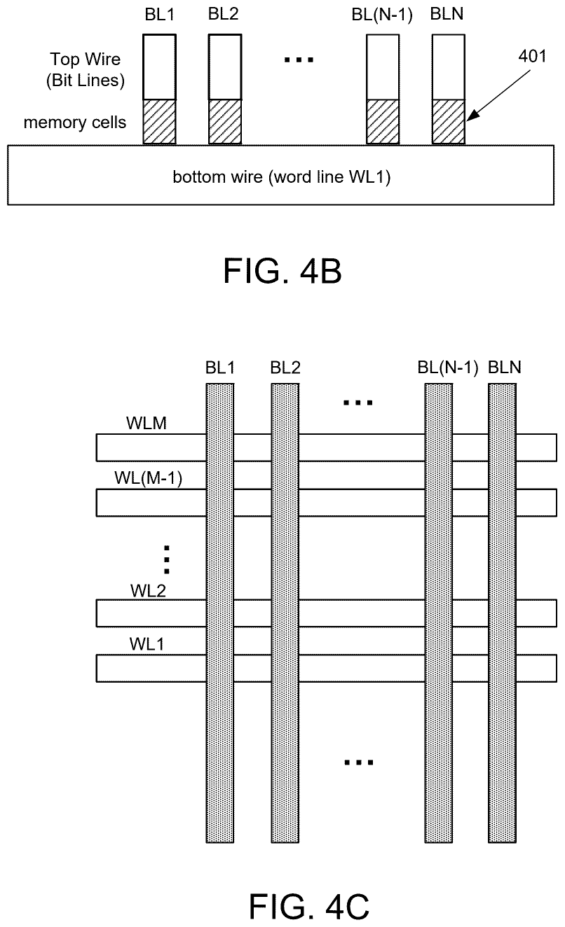

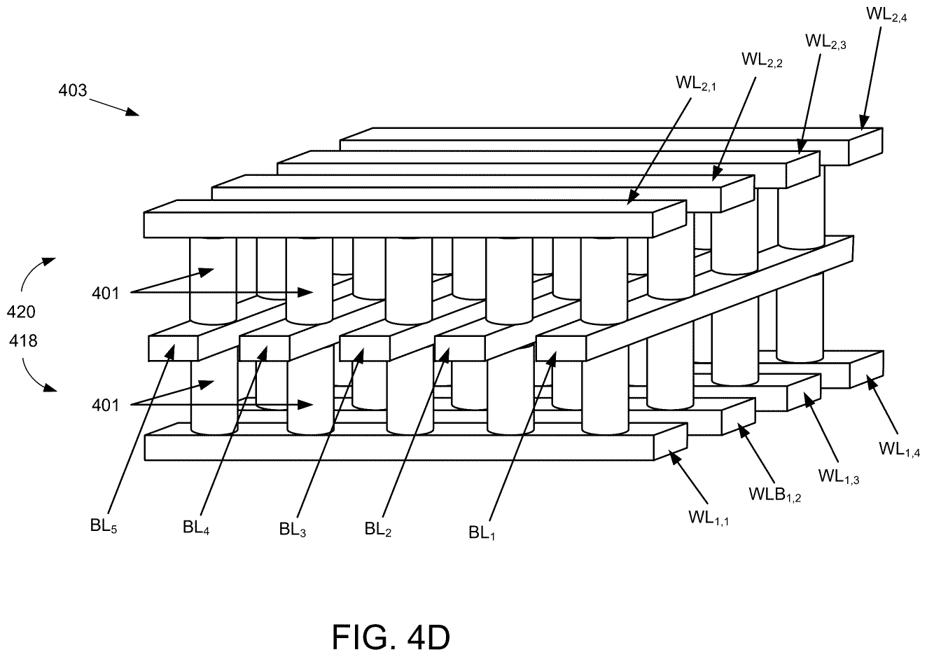

FIG. 4A depicts one embodiment of a portion of a memory array 402 that forms a cross-point architecture in an oblique view. Memory array 402 of FIG. 4A is one example of an implementation for memory structure 202 in FIG. 2 or 3, where a memory die 292 or memory structure die 280 can include multiple such memory arrays 402. The memory array 402 may be included in local memory 140 or host memory 124. The bit lines BL₁-BL₅ are arranged in a first direction (represented as running into the page) relative to an underlying substrate (not shown) of the die and the word lines WL₁-WL₅ are arranged in a second direction perpendicular to the first direction, or diagonal to provide intersections where memory cells are interconnected between WLs and BLs. FIG. 4A is an example of a horizontal cross-point structure in which word lines WL₁-WL₅ and BL₁-BL₅ both run in a horizontal direction relative to the substrate, while the memory cells, two of which are indicated at 401, are oriented so that the current through a memory cell (such as shown at Icell) runs in the vertical direction. In a memory array with additional layers of memory cells, such as discussed below with respect to FIG. 4D, there would be corresponding additional layers of bit lines and word lines. One pattern, for example, would be from the bottom layer: WL, memory cell, BL, memory cell, WL, WL, memory cell, BL memory cell, WL.

As depicted in FIG. 4A, memory array 402 includes a plurality of memory cells 401. The memory cells 401 may include re-writeable memory elements, such as can be implemented using ReRAM, MRAM, PCM, or other material with a programmable resistance. In an embodiment, the memory cells 401 are selector only memory (SOM). The memory cells 401 may be referred to herein as programmable resistance memory cells. One type of programmable resistance memory cell is referred to as an MRAM cell, which is a memory cell that includes a MRAM memory element. The memory cells 401 may also include threshold switching selectors as an additional series element within the memory cells 401, such as can be implemented using an Ovonic Threshold Switch (OTS), Volatile Conductive Bridge (VCB), Metal-Insulator-Metal (MIM), or other material that provides a highly non-linear dependence of current or resistance for varying select voltage. The current in the memory cells of the first memory level is shown as flowing upward as indicated by arrow Icell, but current can flow in either direction to either read or write the memory cell bit state, as is discussed in more detail in the following.

FIGS. 4B and 4C respectively present side and top views of the cross-point structure in FIG. 4A. The sideview of FIG. 4B shows one bottom wire, or word line, WL₁ and the top wires, or bit lines, BL₁-BLₙ. At the cross-point between each top wire and bottom wire is a memory cell 401. The memory cell 401 may be a SOM, MRAM, ReRAM, or other technologies. FIG. 4C is a top view illustrating the cross-point structure for M bottom wires WL₁-WL_{M} and N top wires BL₁-BL_{N}. In a binary embodiment, the memory cell at each cross-point can be programmed into one of two resistance states: high and low. More detail on embodiments for an memory cell design and techniques for their reading are given below. In some embodiments, sets of these wires are arrayed continuously as a “tile,” and such tiles may be paired adjacently in the Word Line (WL) direction and orthogonally in the Bit Line direction to create a module. Such a module may be composed of 2×2 tiles to form a four tile combination wherein the WL drivers between the tiles is “center driven” between the tiles with the WL running continuously over the transistor driver at the approximate center of the line. Similarly, BL drivers may be located between the pair of tiles paired in the BL direction to be center driven, whereby the transistor driver and its area is shared between a pair of tiles. Vias of copper or other types of low resistance may decode and connect the transistor driver/selects to the WL or BL. In addition to the memory element in the memory cell between WL and BL may also be included a series select element such as an OTS.

The cross-point array of FIG. 4A illustrates an embodiment with one layer of word lines and bits lines, with the memory cells sited at the intersection of the two sets of conducting lines. To increase the storage density of a memory die, multiple layers of such memory cells and conductive lines can be formed. A two-layer example is illustrated in FIG. 4D.

FIG. 4D depicts an embodiment of a portion of a two-level memory array that forms a cross-point architecture in an oblique view. As in FIG. 4A, FIG. 4D shows a first layer 418 of memory cells 401 of a memory array 403 connected at the cross-points of the first layer of word lines WL_{1,1}-WL_{1,4} and bit lines BL₁-BL₅ above. Memory array 403 may be included in memory structure 202 of FIG. 2 or 3. A second layer 420 of memory cells is formed above the bit lines BL₁-BL₅ and between these bit lines and a second set of word lines WL_{2,1}-WL_{2,4}. In effect the BLs are shared. In the alternative a second layer may include another deck of BL above the BL shown and below the 2^{nd} deck of WL. Although FIG. 4D shows two layers, 418 and 420, of memory cells, the structure can be extended upward through additional alternating layers of word lines and bit lines in a similar pattern. Depending on the embodiment, the word lines and bit lines of the array of FIG. 4D can be biased for read or program operations such that current in each layer flows from the word line layer to the bit line layer or the other way around. The two layers can be structured to have current flow in the same direction in each layer for a given operation or to have current flow in the opposite directions by driver selection in the positive or negative direction. The memory cell may be placed in the same orientation within the first and second layers enabling use of current in oppositive directions by layer to read or write. Or the memory cell placed in a reversed or flipped direction when placed between the BL and WL in the second layer (enabling use of current in the same direction as is used to read or write in memory cells within the first layer. As will be apparent to someone reasonably skilled in the art, the two layers can be extended to three or more layers.

The use of a cross-point architecture allows for arrays with a small footprint and several such arrays can be formed on a single die. The memory cells formed at each cross-point can be a resistive type of memory cell, where data values are encoded as different resistance levels, either two levels such as with MRAM or into two or more levels for other memory element technologies such as PCM. Depending on the embodiment, the memory cells can be binary valued, having either a low resistance state or a high resistance state, or multi-level cells (MLCs) that can have additional resistance intermediate to the low resistance state and high resistance state. The cross-point arrays described here can be used in the memory die 292 of FIG. 2, the local memory 140 in FIG. 1, and/or the host memory 124 in FIG. 1, or in any other configuration where additional memory is useful. Resistive type memory cells can be formed according to many of the technologies mentioned above, such as ReRAM, PCM, FeRAM, or MRAM.

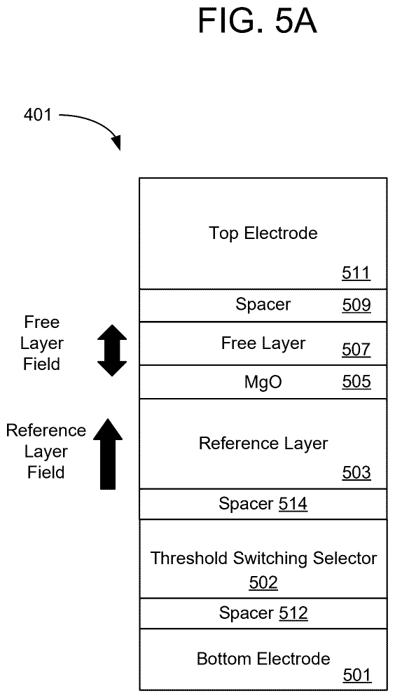

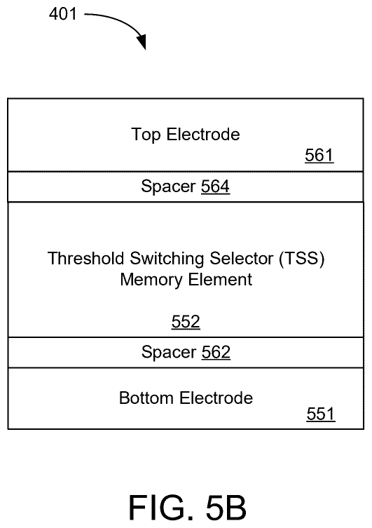

FIG. 5A illustrates the structure of an embodiment for an MRAM cell. The MRAM cell may be used as the programmable resistance memory cell 401 in, for example, FIGS. 4A-4D. The MRAM cell includes a bottom electrode 501, spacer 512, a threshold switching selector 502, spacer 514, a pair of magnetic layers (reference layer 503 and free layer 507) separated by a separation or tunneling layer of, in this example, magnesium oxide (MgO) 505, and then a top electrode 511 separated from the free layer 507 by a spacer 509. The spacer 509 can consist of an MgO capping layer in contact with the free layer 507. The spacer 509 can also contain additional metal layers. In another embodiment, the locations of the reference layer 503 and free layer 507 are switched, with the reference layer 503 on top of MgO 505, and the free layer 507 below MgO 505. In another embodiment, the location of the threshold switching selector 502 is between the free layer 507 and the top electrode 511.

In some embodiments, the bottom electrode 501 is a word line and the top electrode 511 is a bit line. In other embodiments, the bottom electrode 501 is a bit line and the top electrode 511 is a word line. The state of the memory cell is based on the relative orientation of the magnetizations of the reference layer 503 and the free layer 507: if the two layers are magnetized in the same direction, the memory cell will be in a parallel (P) low resistance state (LRS); and if they have the opposite orientation, the memory cell will be in an anti-parallel (AP) high resistance state (HRS). An MLC embodiment would include additional intermediate states. The orientation of the reference layer 503 is fixed and, in the example of FIG. 5A, is oriented upward. Reference layer 503 is also known as a fixed layer or pinned layer. The reference layer 503 can be composed of multiple ferromagnetic layers coupled anti-ferromagnetically in a structure commonly referred to a synthetic anti-ferromagnet or SAF for short.

Data is written to an MRAM memory cell by programming the free layer 507 to either have the same orientation or opposite orientation of the reference layer 503. An array of MRAM memory cells may be placed in an initial, or erased, state by setting all of the MRAM memory cells to be in the low resistance state in which all of their free layers have a magnetic field orientation that is the same as their reference layers. Each of the memory cells is then selectively programmed (also referred to as “written”) by placing its free layer 507 to be in the high resistance state by reversing the magnetic field to be opposite that of the reference layer 503. The reference layer 503 is formed so that it will maintain its orientation when programming the free layer 507. The reference layer 503 can have a more complicated design that includes synthetic anti-ferromagnetic layers and additional reference layers. For simplicity, the figures and discussion omit these additional layers and focus only on the fixed magnetic layer primarily responsible for tunneling magnetoresistance in the cell.

Embodiments disclosed herein include a sequence of applying forming operations to the threshold switching selectors 502 in MRAM cells in a cross-point array. The threshold switching selector 502 has a high resistance (in an off or non-conductive state) until it is biased to a voltage higher than its threshold voltage or current above its threshold current, and until its voltage bias falls below Vhold (also known as “Voffset”) or current below Ihold. After Vth is exceeded and while Vhold is exceeded across the switching selector, the switching selector has a low resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. Accordingly, to program a memory cell at a cross-point, a voltage or current is applied which is sufficient to turn on the associated threshold switching selector and set or reset the memory cell; and to read a memory cell, the threshold switching selector similarly is activated by being turned on before the resistance state of the memory cell is determined. One set of examples for a threshold switching selector is an ovonic threshold switching material of an Ovonic Threshold Switch (OTS). Example threshold switching materials include Ge—Se, Ge—Se—N, Ge—Se—As, Ge—Se—Sb—N, GeSe, GeTe₆, Si—Te, Zn—Te, C—Te, B—Te, Ge—As—Te—Si—N, Ge—As—Se—Te—Si and Ge—Se—As—Te, with atomic percentages ranging from a few percent to more than 90 percent for each element. In an embodiment, the threshold switching selector is a two terminal device. The threshold switching selector 502 can also contain additional conducting layers on the interface with the reference layer 503. For example, spacer 514 is depicted between switching selector 502 and reference layer 503. The spacer layer 514 on the interface with reference layer 503 can be a single conducting layer or composed of multiple conducting layers. The threshold switching selector 502 can also contain additional conducting layers on the interface with the bottom electrode 501. For example, spacer 512 is depicted between switching selector 502 and reference layer 503. The spacer layer 512 on the interface with bottom electrode 501 can be a single conducting layer or composed of multiple conducting layers. Examples of conducting layers adjacent to the OTS include carbon, carbon nitride, carbon silicide, carbon tungsten, titanium, titanium nitride, tungsten, tungsten nitride, tantalum, tantalum nitride, and others. Threshold voltage switches have a Threshold Voltage (Vth) above which the resistance of the device changes substantially from insulating, or quasi insulating, to conducting.

In an embodiment, a current-force approach is used to access the MRAM cell. The current-force approach may be used to read or write the MRAM cell. In an embodiment, current-force approach is used to lower the threshold voltage of a threshold switching selector in a programmable resistance memory cell. In the current-force approach, an access current (e.g., I_{read}, I_{write}, I_{drive}) is driven through the bottom electrode 501 by a current driver. The current will be provided by a transistor or resistor based current source. In an embodiment, the current driver may be a part of the address selected row driver circuitry (e.g., array drivers 224) for the electrode 501. However, alternatively the current driver may be a part of the address selected column driver circuitry (e.g., driver circuitry 214) for the electrode 501. A voltage (e.g., V_{select}) is provided to the top electrode 511. Herein, the terms “read current” (I_{read}) and “write current” (I_{write}) will be used in connection with access currents that are driven through MRAM cells (or other programmable resistance cells). The write current may change the state of the MRAM cell. As an example, a write current of about 30 pA for 50 ns may be used for an MRAM cell with a Critical Dimension (CD) of approximately 20 nanometers with RA 10 Ωμm² to switch the MRAM state from the P-state to the AP-state. Read currents may be about half the write current if applied for a limited time, such as <20 ns. A write current that flows in one direction through the MRAM cell will change an AP-state MRAM cell to the P-state. A write current that flows in the other direction, such as in the read direction, through the MRAM cell will change a P-state MRAM cell from the P-state to the AP-state. In general until the cell state is determined or a voltage level is captured and stored that correlates to the memory cell state, a read current will preferably be set low enough and the read duration short enough so as not to change the state of an MRAM cell from the P-state to the AP-state or from the AP-state to the P-state during read. Typically the write current required to switch the MRAM state from the P-state to the AP-state is larger in absolute magnitude than the write current required to switch the MRAM state from the AP-state to the P-state, so this may be a preferred direction to read for offering my margin against a state change before the bit state is correctly sensed. Current magnitudes may be adjusted accordingly by write direction, or the current used for P to AP if a single magnitude is used.

In some embodiments, a read current may be applied in a P2AP direction or, alternatively, in an AP2P direction. In some embodiments, the MRAM cell is read by performing an SRR (self-referenced-read). In one embodiment, the SRR has a first read (Read1 in the P2AP direction), a first write (Write 1 to the AP-state), and a second read (Read2 in the P2AP direction). Then the original state of the cell may be restored by a second write (Write_Back to the P-state for bits initially in the P-state). Or in another embodiment, the SRR read current and destructive write currents are both reversed; for example when addressing the second layer with a memory cell oriented the same as in the first layer.

In an embodiment, the voltage level of the memory cell due to Read1 in the P2AP direction is sensed and stored, for example on a capacitor; or by conversion to digital bits by an Analog to Digital converter and the bits stored in memory, for example in SRAM until after use in Read 2. The state stored on a capacitor can be adjusted, for example, 150 mv positive or negative by forcing a voltage on one terminal of a capacitor connected to the storage capacitor. Or the digital stored level can be adjusted by digitally adding or subtracting 150 mV to the stored bits. The 150 mV can be adjusted to be dependent on the typical bit resistance. For example, if the bit low resistance state is 25K ohms and the high resistance 50K ohms, the difference is 25 K ohms. If the read current is 15 μA, the difference voltage between the states if 25K ohms×15 μA=375 m V, making a choice of 150 mV acceptable but perhaps suggesting 187.5 mV may be more optimum, for example.

Although the foregoing describes reads in the P2AP direction and destructive writes to the AP-state (with write back after SRR to the P-state), in an alternative embodiment the first SRR has a first read (Read1 in the AP2P direction), a destructive write (Write 1) to the P-state and a second read (Read2) in the AP2P direction.

In one embodiment, the MRAM cell is read by applying, for example, approximately OV to the top electrode 511 by turning on a transistor connected between 511 and a power supply, while driving a current of, for example, 15 micro-Amperes (μA) through the bottom electrode 501. This read current may flow from the bottom electrode 501 to the top electrode 511. Note that the read may be Read1 or Read2 in the P2AP direction. P2AP means current flows in the direction that would write the bit from P to AP or AP to AP. In some embodiments, data is written to the MRAM cell using a bipolar write operation. In one embodiment, the MRAM cell is written from the AP-state to the P-state by applying, for example, 3 V to the top electrode 511, while driving a write current of, for example, −30 μA through the bottom electrode 501. This write current will flow from the top electrode 511 to the bottom electrode 501. In one embodiment, the MRAM cell is written from the P-state to the AP-state by applying, for example, 0 V to the top electrode 511, while driving a current of, for example, 30 μA through the bottom electrode 501. This write current will flow from electrode 501 to the electrode 511.

As an alternative to the approach in FIG. 5A, the select voltage can be applied to the bottom electrode 501 with the access current applied through the top electrode 511. In one such embodiment, the MRAM cell is read by applying, for example, 3 V to the bottom electrode 501, while driving a read current of, for example, −15 μA through the top electrode 511. This read current may flow from the bottom electrode 501 to the top electrode 511.

In one embodiment, the MRAM cell is written from the AP-state to the P-state by applying, for example, −3 V to the bottom electrode 501, while driving a write current of, for example, 30 μA through the top electrode 511. The electron current will flow from the bottom electrode 501 to the top electrode 511. In one embodiment, the MRAM cell is written from the P-state to the AP-state by applying, for example, OV to the bottom electrode 501, while driving a current of, for example, −30 μA through the top electrode 511. The electron current will flow from the top electrode 511 to the bottom electrode 501. The direction of the current polarity to switch the magnetization of the bit into the P or AP state can vary based on reference layer design and the location of the reference layer with respect to the free layer.

Some biasing techniques may result in voltage across non-selected memory cells of the array, which can induce “leakage” currents in non-selected memory cells. Although this wasted power consumption can be mitigated to some degree by designing the memory cells to have relatively high resistance levels for both high and low resistance states when WL or BL is address unselected, this overhead leakage will still result in increased current and power consumption as well as placing additional design constraints on the design of the memory cells and the array due to lack of read and write margin. One approach to address this unwanted current leakage is to place a selector element in series with each MRAM or other resistive (e.g., ReRAM, PCM) memory cell. For example, a select transistor can be placed in series with each resistive memory cell element in FIGS. 4A-4D so that the memory cells 401 is now a composite of a select transistor and a programmable resistance. Such an architecture may be referred to as 1T1R. Use of a select transistor, however, requires the introduction of additional control lines and cell area to be able to turn on the corresponding transistor of a selected memory cell. Additionally, transistors will often not scale in the same manner as the resistive memory element write current, so that as memory arrays move to smaller sizes the use of transistor based selectors can be a limiting factor in reducing cost, for example. An alternate approach to select transistors is the use of a threshold switching selector (e.g., threshold switching selector 502) in series with the programmable resistive element. A two terminal threshold switching selector does not require the aforementioned additional control lines and additional cell area to be able to turn on the corresponding select transistor of a selected memory cell. In some embodiments, the memory system performs a read as disclosed herein to read memory cells having a two terminal threshold switching selector in series with a programmable resistance memory element.

FIG. 5B illustrates the structure of an embodiment for an SOM cell. The SOM cell may be used as the programmable resistance memory cell 401 in, for example, FIGS. 4A-4D. The SOM cell includes a bottom electrode 551, spacer 562, a threshold switching selector (TSS) memory element 552, spacer 564, and a top electrode 561. In some embodiments, the bottom electrode 551 is a word line and the top electrode 561 is a bit line. In other embodiments, the bottom electrode 551 is a bit line and the top electrode 561 is a word line. The state of the memory cell is based on the state of the TSS memory element 552. Embodiments disclosed herein include a sequence of applying forming operations to the TSS memory element 552 in SOM cells in a cross-point array.

Data is written to an SOM memory cell by programming the TSS memory element 552 with a program (or write) signal (e.g., program current, program voltage) having a desired polarity. In one embodiment, the SOM memory cell is programmed to a first state (WO) using a first polarity program signal and to a second state (W1) using a second polarity program signal. The SOM memory cell may be read using a read signal (e.g., read current, read voltage). The polarity of the read signal relative to the polarity of the program signal may impact the Vth of the SOM cell. In an embodiment, a read signal having the same polarity as the program signal results in a lower Vth than a read signal having the opposite polarity as the program signal. Typically, the memory system will choose a polarity for the read signal and then be consistent with that polarity of read signal when determining the state of the SOM cell. Therefore, the polarity of the program signal will, in effect, result in a higher/lower Vth when read with the chosen polarity read signal.

The threshold switching selector 552 may also serve as a selector to select the memory cell for a memory operation. The threshold switching selector 552 has a high resistance (in an off or non-conductive state) until it is biased to a voltage higher than its threshold voltage (Vth) or current above its threshold current, and until its voltage bias falls below Vhold (also known as “Voffset”) or current below Ihold. After the Vth is exceeded and while Vhold is exceeded across the switching selector, the switching selector has a low resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. Accordingly, to select a memory cell at a cross-point, a voltage or current is applied which is sufficient to turn on the associated threshold switching selector. One set of examples for a threshold switching selector is an ovonic threshold switching material of an Ovonic Threshold Switch (OTS). Example threshold switching materials include Ge—Se, Ge—Se—N, Ge—Se—As, Ge—Se—Sb—N, Ge58Se42, GeTe₆, Si—Te, Zn—Te, C—Te, B—Te, Ge—As—Te—Si—N, Ge—As—Se—Te—Si and Ge—Se—As—Te, with atomic percentages ranging from a few percent to more than 90 percent for each element. In an embodiment, the threshold switching selector is a two terminal device. The threshold switching selector 552 can also contain additional conducting layers. For example, spacer 564 is depicted between switching selector 552 and top electrode 561. The spacer layer 564 can be a single conducting layer or composed of multiple conducting layers. The threshold switching selector 552 can also contain additional conducting layers on the interface with the bottom electrode 551. For example, spacer 562 is depicted between switching selector 552 and bottom electrode 551. The spacer layer 562 on the interface with bottom electrode 551 can be a single conducting layer or composed of multiple conducting layers. Examples of conducting layers adjacent to the OTS include carbon, carbon nitride, carbon silicide, carbon tungsten, titanium, titanium nitride, tungsten, tungsten nitride, tantalum, tantalum nitride, and others. Threshold voltage switches have a Threshold Voltage (Vth) above which the resistance of the device changes substantially from insulating, or quasi insulating, to conducting.

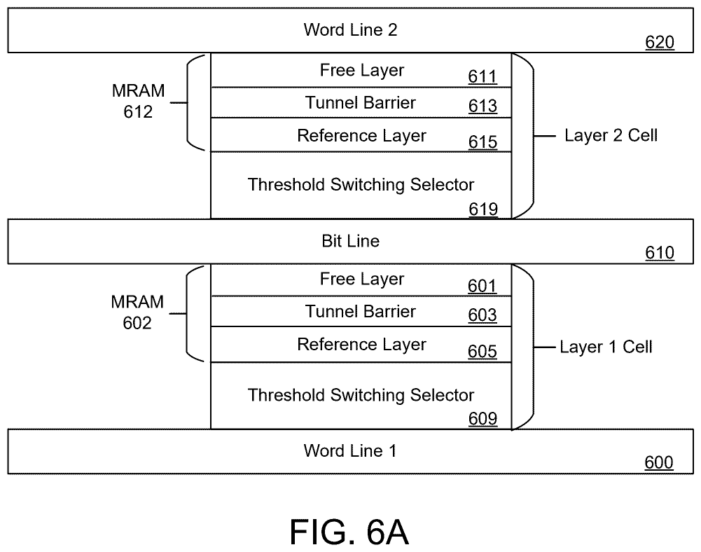

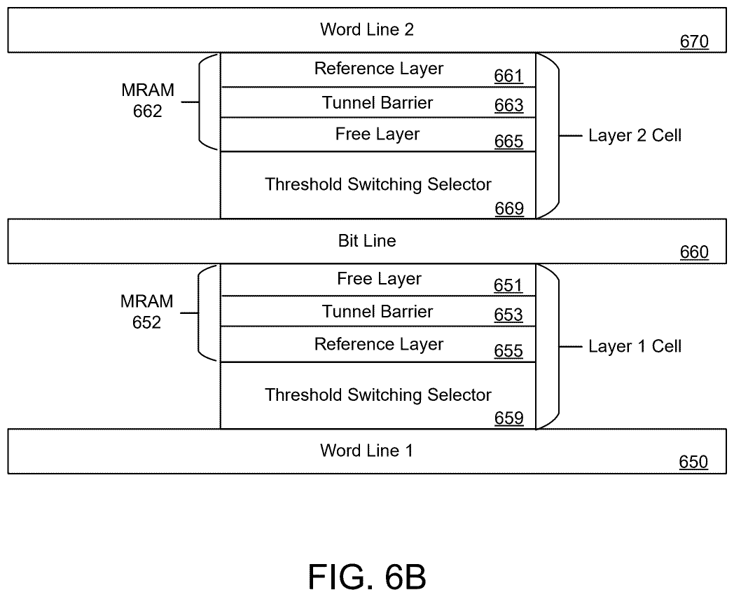

FIGS. 6A and 6B illustrate embodiments for the incorporation of threshold switching selectors into an MRAM memory array having a cross-point architecture. The examples of FIGS. 6A and 6B show two MRAM cells (Layer 1 Cell, Layer 2 Cell) in a two layer cross-point array, such as shown in FIG. 4D, but in a side view. Keeping the orientation of the MRAM layers the same in the Layer 1 Cell and the Layer 2 Cell, as depicted in FIG. 6A, allows the fabrication process to be the same for each layer. Whereas 6B has the memory cell inverted which allows the drive circuitry to work the same; e.g., BL goes Low to Read P2AP for each layer. FIGS. 6A and 6B show a lower first conducting line of word line 1 600, an upper first conducting line of word line 2 620, and an intermediate second conducting line of bit line 610. In these figures, all of these lines are shown running left to right across the page for ease of presentation, but in a cross-point array they would be more accurately represented as in the oblique view of FIG. 4D where the word lines, or first conducting lines or wires, run in one direction parallel to the surface of the underlying substrate and the bit lines, or second conducting lines or wires, run in a second direction parallel to the surface to the substrate that is largely orthogonal to the first direction. The MRAM memory cells are also represented in a simplified form, showing only the reference layer, free layer, and the intermediate tunnel barrier, but in an actual implementation would typically include the additional structure described above with respect to FIG. 5.

An MRAM element 602 including free layer 601, tunnel barrier 603, and reference layer 605 is formed above the threshold switching selector 609, where this series combination of the MRAM element 602 and the threshold switching selector 609 together form the layer 1 cell between the bit line 610 and word line 1 600. The series combination of the MRAM element 602 and the threshold switching selector 609 operate largely as described above when the threshold switching selector 609 is turned on. Initially, though, the threshold switching selector 609 needs to be turned on by applying a voltage above the threshold voltage Vth of the threshold switching selector 609, and then the biasing current or voltage needs to be maintained high enough above the holding current or holding voltage of the threshold switching selector 609 so that it stays on during the subsequent read or write operation.

On the second layer, an MRAM element 612 includes free layer 611, tunnel barrier 613, and reference layer 615 is formed above the threshold switching selector 619, with the series combination of the MRAM element 612 and the threshold switching selector 619 together forming the layer 2 cell between the bit line 610 and word line 2 620. The layer 2 cell will operate as for the layer 1 cell, although the lower conductor now corresponds to a bit line 610 and the upper conductor is now a word line, word line 2 620. Additional paired layers may similarly share another bit line between them, having a pattern of WL₁ , BL1, WL2; WL3, BL2, WL4; or have separate bit lines in a pattern such as WL₁ , BL1, WL2, BL2. Or separate bit lines in a pattern of WL₁ , BL1, BL2, WL2.

In the embodiment of FIG. 6A, the threshold switching selector 609/619 is formed below the MRAM element 602/612, but in alternate embodiments the threshold switching selector can be formed above the MRAM element for one or both layers. The MRAM memory cell is directional. In FIG. 6A, the MRAM elements 602 and 612 have the same orientation, with the free layer 601/611 above (relative to the unshown substrate) the reference layer 605/615. Forming the layers between the conductive lines with the same structure can have a number of advantages, particularly with respect to processing as each of the two layers, as well as subsequent layers in embodiments with more layers, can be formed according to the same processing sequence.

FIG. 6B illustrates an alternate embodiment that is arranged similarly to that of FIG. 6A, except that in the layer 2 cell the locations of the reference layer and free layer are reversed. More specifically, between word line 1 650 and bit line 660, as in FIG. 6A the layer cell 1 includes an MRAM element 1 having a free layer 651 formed over tunnel barrier 653, that is turn formed over the reference layer 655, with the MRAM element 652 formed over the threshold switching selector 659. The second layer of the embodiment of FIG. 6B again has an MRAM element 662 formed over a threshold switching selector 669 between the bit line 660 and word line 2 670, but, relative to FIG. 6A, with the MRAM element 662 inverted, having the reference layer 661 now formed above the tunnel barrier 663 and the free layer 665 now under the tunnel barrier 663. Alternatively, the configuration of MRAM element 662 may be used for the Layer 1 cell and the configuration of MRAM cell 652 may be used for the Layer 2 cell.

Although the embodiment of FIG. 6B requires a different processing sequence for the forming of layers, in some embodiments it can have advantages. In particular, the directionality of the MRAM structure can make the embodiment of FIG. 6B attractive since when writing or reading in the same direction (with respect to the reference and free layers) the bit line will be biased the same for both the lower layer and the upper layer, and both word lines will be biased the same. For example, if both layer 1 and layer 2 memory cells are sensed in the P2AP direction (with respect to the reference and free layers), the bit line layer 660 will be biased such as in the P2AP direction, the bit line 660 is biased low (e.g., 0 V) for both the upper and lower cell, with word line 1 650 and word line 2 670 both biased to a higher voltage level. Similarly, with respect to writing, for writing to the high resistance AP state the bit line 660 is biased low (e.g., 0 V) for both the upper and lower cell, with word line 1 650 and word line 2 670 both biased to a higher voltage level.

To either read data from or write data to an MRAM memory cell involves passing a current through the memory cell. In embodiments where a threshold switching selector is placed in series with the MRAM element, before the current can pass through the MRAM element the threshold switching selector may be turned on by applying a sufficient voltage across and current through the series combination of the threshold switching selector and the MRAM element.

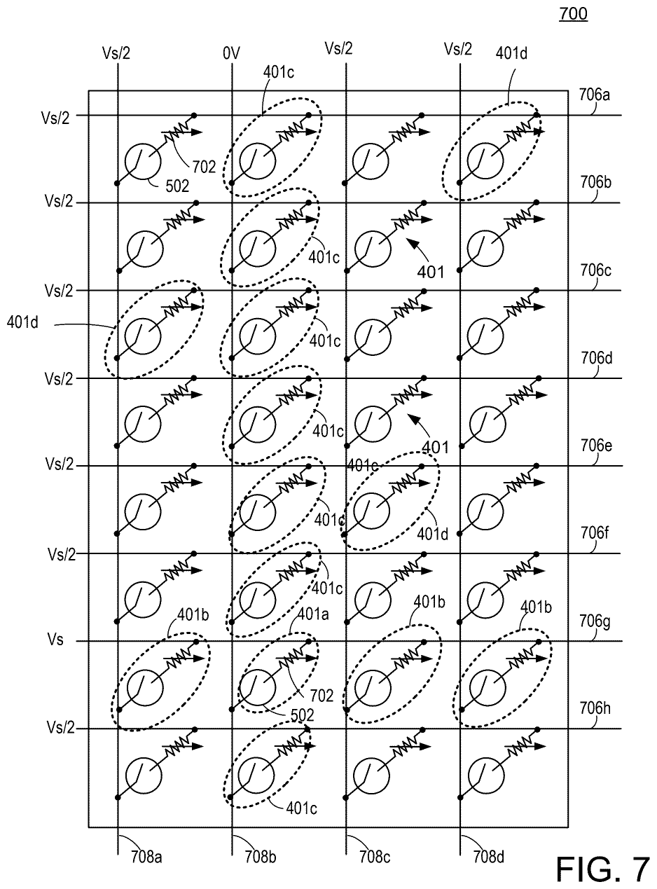

FIG. 7 depicts an embodiment of a memory array 700 having a cross-point architecture. The memory array 700 may be included in memory structure 202 of FIG. 2 or 3. The array 700 has a set of first conductive lines 706a-706h and a set of second conductive lines 708a-708d. In one embodiment, the set of first conductive lines 706a-706h are word lines and the set of second conductive lines 708a-708b are bit lines. For ease of discussion, the set of first conductive lines 706a-706h may be referred to as word lines and the set of second conductive lines 708a-708b may be referred to as bit lines. However, the set of first conductive lines 706a-706h could be bit lines and the set of second conductive lines 708a 708b could be word lines.

The memory array 700 has a number of programmable resistance memory cells 401. Each memory cell 401 is connected between one of the first conductive lines 706 and one of the second conductive lines 708 (e.g., at the cross point of one of the first conductive lines 706 and one of the second conductive lines 708). Each memory cell has a programmable resistance memory element 702 in series with a threshold switching selector 502. In one embodiment, the programmable resistance memory element includes a magnetoresistive random access memory (MRAM) element. The threshold switching selector 502 is configured to become conductive with lower resistance in response to application of a voltage level exceeding a threshold voltage of the threshold switching selector 502, and remains conductive with lower resistance until the current through the switching selector 502 is reduced below the selector holding current, Ihold. The threshold switching selector 502 may be a two terminal device. In an embodiment, the threshold switching selector 502 comprises an OTS.

Embodiments are disclosed herein for the sequence in which forming operations are applied to the threshold switching selectors 502 in the cross point array 700. For purpose of discussion, memory cell 401a is being selected for forming the threshold switching selector 502. Selected memory cell 401 a is at the cross-point of selected word line 706g and selected bit line 708b. A selected memory cell means a memory cell that is selected for a memory operation such as seasoning, read, or write. A selected memory cell is connected between a selected word line and a selected bit line. To form a selected memory cell 401, a select voltage such as near ground is provided to the selected bit line (e.g., bit line 708b) and forming voltage (Vs) is applied to a selected word line (e.g., word line 706g). A selected word line means that the word line is connected to at least one selected memory cell. Alternatively, the memory cell could be selected by applying the forming voltage (Vs) to the selected bit line while applying a select voltage to the selected word line. More generally, the forming voltage (Vs) is applied across the selected memory cell. For example, an alternative is to apply +Vs/2 to the selected word line and −Vs/2 to the selected bit line, with OV applied to unselected word lines and unselected bit lines.

In one approach word lines that are not connected to the selected memory cell may be driven by a voltage that is approximately one-half the magnitude of the forming voltage. As depicted in FIG. 7, word lines 706a, 706b, 706c, 706d, 706e, 706f, and 706h each have what is referred to as a half-select voltage (Vs/2) applied thereto. The half-select voltage (Vs/2) has approximately one-half the magnitude of the forming voltage (Vs). The term “half-selected memory cell,” as defined herein, is a memory cell that has approximately ½ of the voltage across it compared to the selected memory cell.

In one approach bit lines that are not connected to the selected memory cell may be driven by a voltage that is approximately one-half the magnitude of the forming voltage. As depicted in FIG. 7, bit lines 708a, 708c, and 708d each have what is referred to as a half-select voltage (Vs/2) applied thereto. Alternative biasing schemes may be used if, for example, Vs/2 is applied to the selected word line and −Vs/2 is applied to the selected bit line. As noted above, the half-select voltage (Vs/2) has approximately one-half the magnitude of the forming voltage (Vs).

Unselected memory cells connected to the selected word line are what is referred to herein as half-selected memory cells. The voltage across a half-selected memory cell is approximately half of the voltage across a selected memory cell. The half-selected memory cells 401b connected to the selected word line each have Vs applied to the selected word line and Vs/2 applied to their respective bit lines. Therefore, half-selected memory cells 401b each have Vs/2 applied across the memory cell.

Unselected memory cells connected to the selected bit line are what is referred to herein as half-selected memory cells. The voltage across these half-selected memory cell is approximately half of the voltage across the selected memory cell. The half-selected memory cells 401c connected to the selected bit line each have 0 V applied to the selected bit line and Vs/2 applied to their respective word lines. Therefore, half-selected memory cells 401c each have Vs/2 applied across the memory cell.

Memory cells connected to both an unselected word line and an unselected bit line are completely unselected by which it is meant they have approximately OV across the memory cell. A few of the completely unselected memory cells 401d are pointed out in FIG. 7. In this example, each completely unselected memory cell 401d has Vs/2 applied to its word line and Vs/2 applied to its bit line. The threshold switching selector 502 of completely unselected memory cells 401d will not turn on even if the threshold voltage of the threshold switching selector 502 is somewhat lower than a target Vth range.

The threshold switching selector 502 in half-selected memory cells 401b, 401c should not turn on during operations such a forming, read, or write. However, if the Vth of the threshold switching selector 502 is less than Vs/2 then the threshold switching selector 502 could turn on during a forming operation. Techniques are disclosed herein for preventing (or at least reducing the chance of) the threshold switching selectors 502 in half-selected memory cells 401b, 401c from turning on during a forming operation. In an embodiment, the sequence in which the memory cells are selected for forming is selected to reduce the likelihood of the threshold switching selectors 502 in half-selected memory cells 401b, 401c turning on during the forming operation.

In the example of FIG. 7 there are more word lines than bit lines in the cross-point array. In another embodiment, there are more bit lines than word lines in the cross-point array. In another embodiment, the number of bit lines equals the number of word lines in the cross-point array. In the example of FIG. 7 there are twice as many word lines as bit lines in the cross-point array; however, a different ratio could be used. Thereby, different tile sizes may be realized. For example, a tile may have 1024 BL by 2048 WL, which may be composed into a module of 2048×4096 cells by center driving the WL and BL between the four tiles. In one embodiment, forming is performed on a group of memory cell by, for example, selecting one memory cell in each of a number of tiles.

In an embodiment, the memory system applies a forming signal to progressively lower the threshold voltage of the threshold switching selectors 502 over a number of forming cycles. The magnitude of the forming signal is lowered with each forming cycle. In an embodiment, the forming signal is a forming voltage. In an embodiment, the forming signal includes a forming current. In an embodiment, the forming signal has a magnitude and duration that is sufficient to partially form the threshold switching selector of the cell that has been selected for forming. Partial forming means that the Vth is lowered somewhat, but multiple forming cycles are used to fully form the threshold switching selector 502. Therefore, the threshold switching selector may be partially formed over a number of forming cycles until a target operating Vth is reached. For example, multiple forming cycles may be used to lower the Vth of the threshold switching selector from Vinit to an operating state having an operating threshold voltage (Vop)

In some embodiments, a voltage-force technique is used to access memory cells in a cross-point memory array. In other embodiments, a current-force approach is used to access memory cells in a cross-point memory array. In an embodiment of a current-force approach a current is applied to the selected word line, as opposed to applying a voltage to the selected word line. However, voltages may still be applied to the selected bit line and to the unselected word lines and the unselected bit lines, similar to the voltage-force approach. To select memory cell 401a, a select voltage (V_{select_BL}) such as near ground is provided to the selected bit line (e.g., bit line 708b) and an access current (I_{access}) is driven (or forced) to a selected word line (e.g., word line 706g). The access current charges up the voltage on the selected word line 706g. There is a limit to how high the voltage on the selected word line 706g may reach (e.g., a compliance voltage). In one embodiment, V_{select_BL} has an adequate magnitude such that the threshold switching selector 502 in a selected memory cell will turn on, assuming that I_{access} is applied to the selected word line with adequate compliance voltage relative to the BL voltage. For example, V_{select_BL} may be approximately 0 V. On the other hand, V_{unsel_BL} has a magnitude such that the threshold switching selector 502 in an unselected memory cell will not turn on, for example V_{unsel BL} may be approximately 1.65 V if the positive power supply is 3.3 V. Access current (I_{access}) is driven through at least a portion of selected word line 706g after the OTS is turned on. This access current may also flow through the selected memory cell 401a and in a portion of selected bit line 708b after the OTS is turned on. Such a selected WL may, for example, be driven high by 15 μA to read or 30 μA to write by a current source with compliance voltage of, for example, 3.3 V. To write the opposite polarity, the selected word line is forced, for example, with −30 μA and the selected bit line to near 3.3 V.

Word lines and bit lines that are not selected are referred to as unselected word lines or unselected bit lines, respectively. In one embodiment, a word line or bit line may be unselected by forcing them to an unselect voltage, such as Vmid, for example 1.65 V, at approximately one half the drive compliance voltage; e.g., 3.3 V. An unselect voltage (V_{unsel_BL}) is provided to the unselected bit lines (e.g., bit lines 708a, 708c, 708d). An unselect voltage (V_{unsel_WL}) such as Vmid is provided to the unselected word lines (e.g., word lines 706a, 706b, 706c, 706d, 706e, 706f, and 706h). I_{access} could flow in either direction through the selected word line (as well as the selected bit line). In one embodiment, no current other than leakage is forced through unselected word lines (e.g., 706a, 706b, 706c, 706d, 706e, 706f, and 706h).

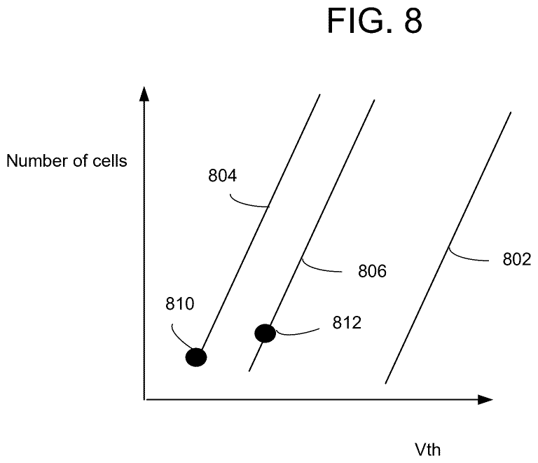

When a forming operation is applied to an embodiment of a programmable resistance memory cell the Vth of the memory cell drops. For some types of memory cells the Vth may increase over time after this initial drop. FIG. 8 is a graph depicting example Vth distributions for memory cells. Vth distribution 802 is for memory cells that have not yet undergone a forming operation. Vth distribution 804 is for memory cells just after undergoing a forming operation. The forming operation lowers the Vth. For some types of memory cells the Vth may increase over time after this initial Vth drop. Vth distribution 806 is a “relaxed” Vth distribution for memory cells showing an increase to the Vth after some time has passed since the forming operation. The Vth increase may be logarithmic in which the Vth may increase fairly rapidly at first but more slowly over time.

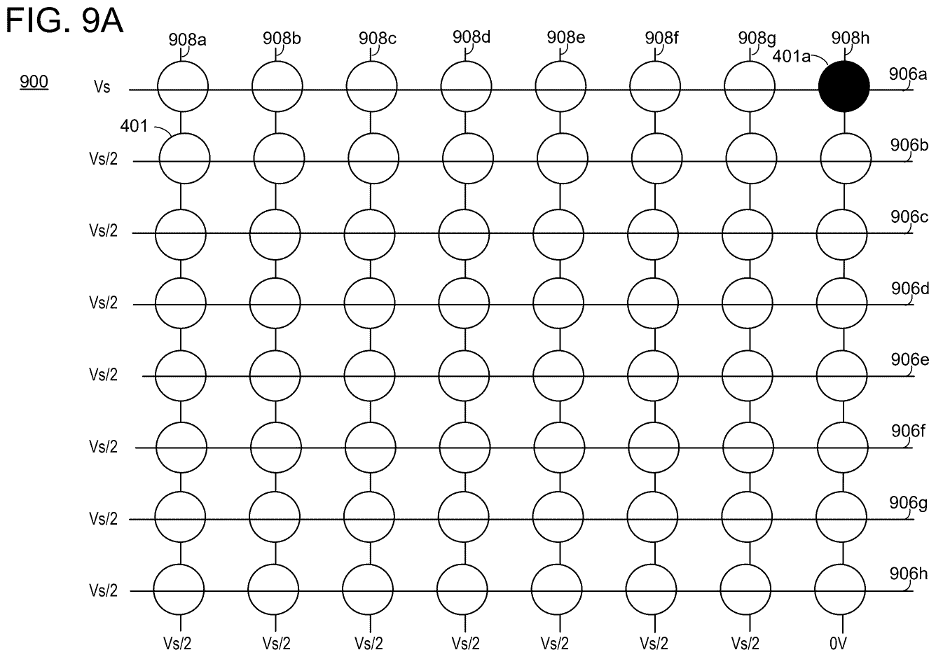

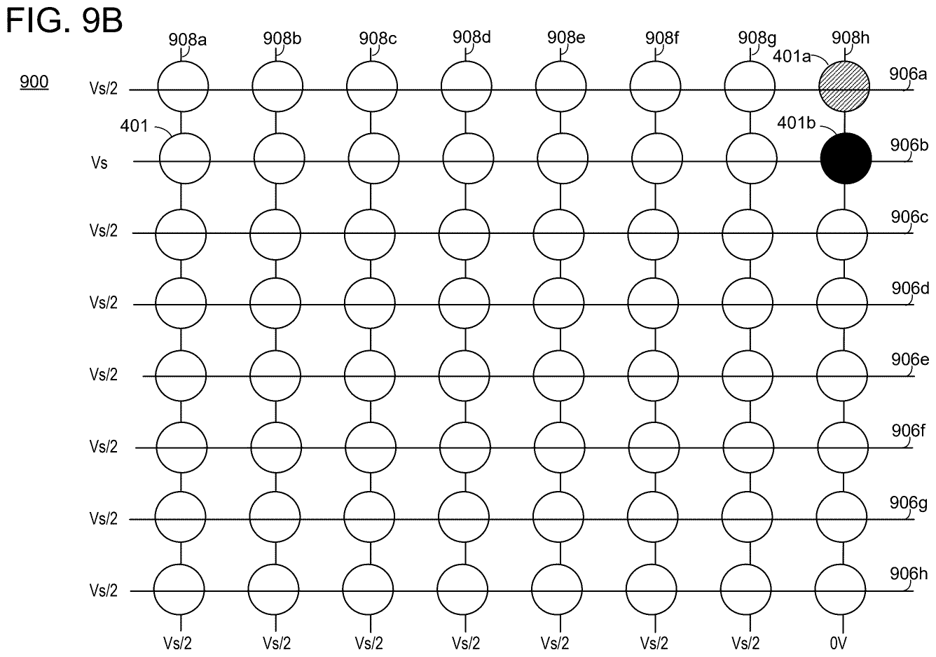

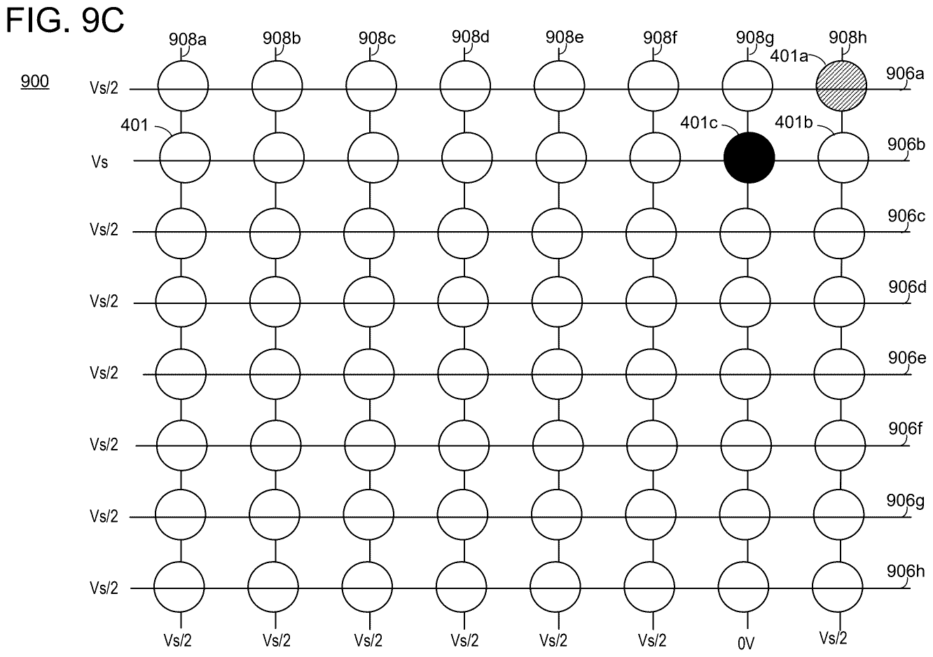

FIG. 9A depicts an example cross-point array 900 that will be referred to in order to discuss issues with performing forming operations on the memory cells 401 in the cross-point array 900. Memory cell 401a is presently selected for a forming operation. Therefore, Vs is applied to word line 906a and 0 V is applied to bit line 908h. All unselected word lines 906b-906h and all unselected bit lines 908a-908g have Vs/2 applied thereto. In this example, memory cell 401a is the first memory cell 401 in the array 900 to have the forming operation. Thus, all of the other memory cells 401 should have a high Vth (see plot 802 in FIG. 8). The half-selected cells on word line 906a and bit line 908h should thus all have a high Vth. These half-selected cells on word line 906a and bit line 908h each have Vs/2 applied across the cell 401. As long as the Vth of these half-selected cells is greater than Vs/2 the memory cell should not turn on, which is desirable. As noted above in the discussion of FIG. 7, alternative biasing schemes may be used such as applying +Vs/2 to the selected word line and −Vs/2 to the selected bit line, with 0 V applied to unselected word lines and unselected bit lines.

FIG. 9B depicts the example cross-point array 900 in which memory cell 401b is presently selected for a forming operation. Therefore, Vs is applied to word line 906b and 0 V is applied to bit line 908h. In this example, memory cell 401b is the second memory cell 401 in the array 900 to have the forming operation. Thus, memory cell 401a now has a lower Vth. Referring to FIG. 8, memory cell 401a now has its Vth on curve 804, as represented by the point 810 on curve 804. All of the other memory cells 401 should still have a high Vth (see plot 802 in FIG. 8). Note, however, that memory cell 401a is a half-selected cell with Vs/2 applied across memory cell 401a. If the Vth of memory cell 401a is less than Vs/2 then memory cell 401a may fire (e.g., turn on), which is an undesirable half-select event. Furthermore note that any undesirable half-select events can result in a lower voltage across the memory cell selected for the forming operation, thereby impairing the forming operation. Note that as the Vth reduces, the leakage current of the memory cell may increase which can lead to a higher IR drop on the word line and/or bit line. The higher IR drop will result in a lower voltage across the memory cell selected for the forming operation. Also note that the foregoing half-select issue applies if any of the memory cells on word line 906a or bit line 908h were to be the second selected memory cell. Furthermore, the foregoing half-select issue applies (although to a lesser extent as time passes) for the third selected memory cell, fourth selected memory cell, etc.

FIG. 9C depicts the example cross-point array 900 in which memory cell 401c is the second memory cell 401c selected for forming (after cell 401a). Therefore, Vs is applied to word line 906b and 0 V is applied to bit line 908g. Since memory cell 401 a has just received the forming operation it now has a lower Vth. Referring to FIG. 8, memory cell 401a now has its Vth on curve 804, as represented by the point 810 on curve 804. All of the other memory cells 401 should still have a high Vth (see plot 802 in FIG. 8). In contrast with the example in FIG. 9B, memory cell 401a is not a half-selected cell. Instead memory cell 401a is a fully unselected cell with 0 V applied across memory cell 401a. Therefore, memory cell 401a should not fire (turn on) even if it has a relatively low Vth. Therefore, the sequence for performing the forming operations prevents undesirable half-select events.

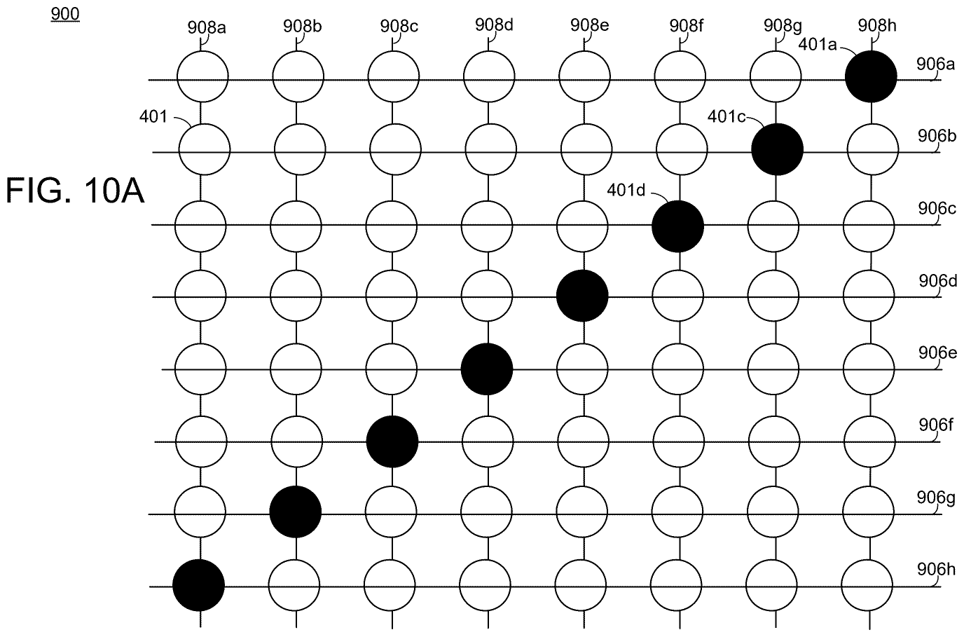

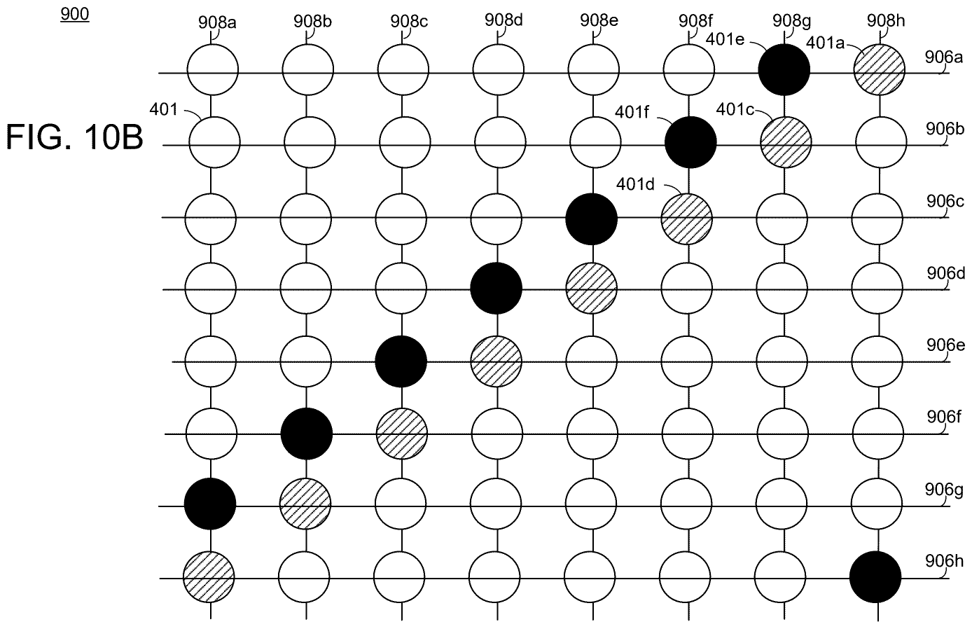

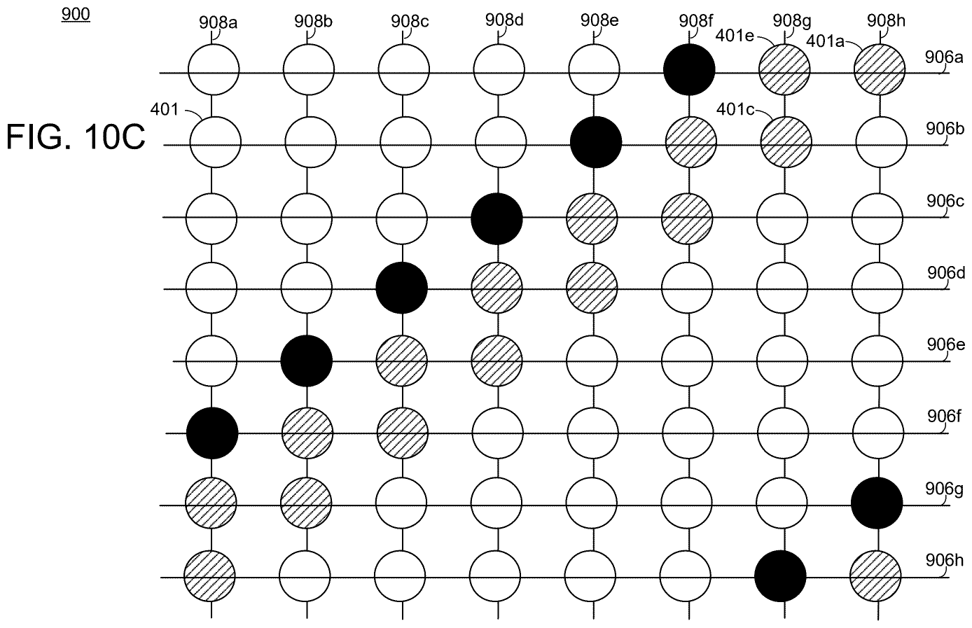

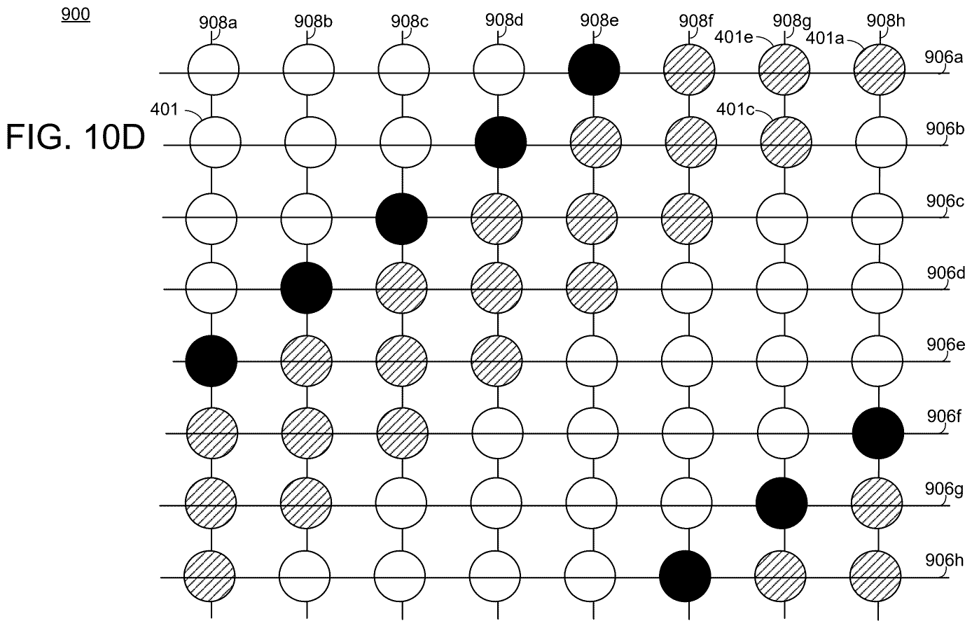

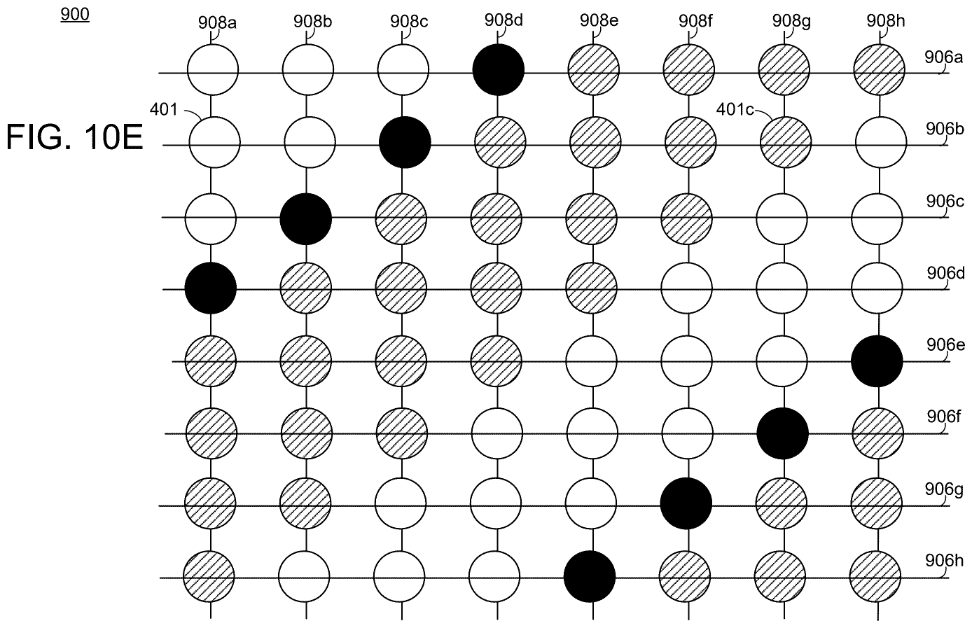

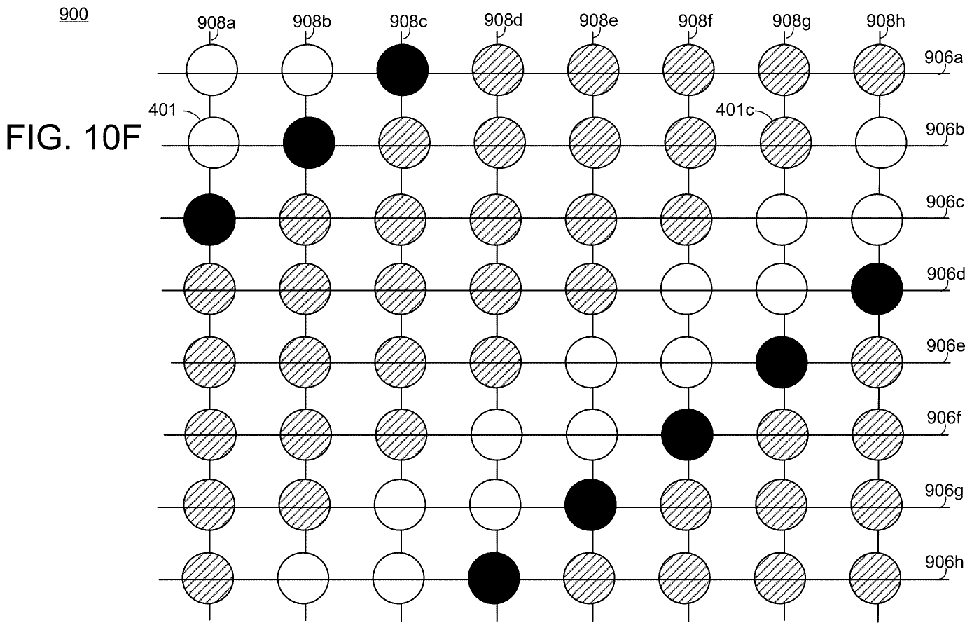

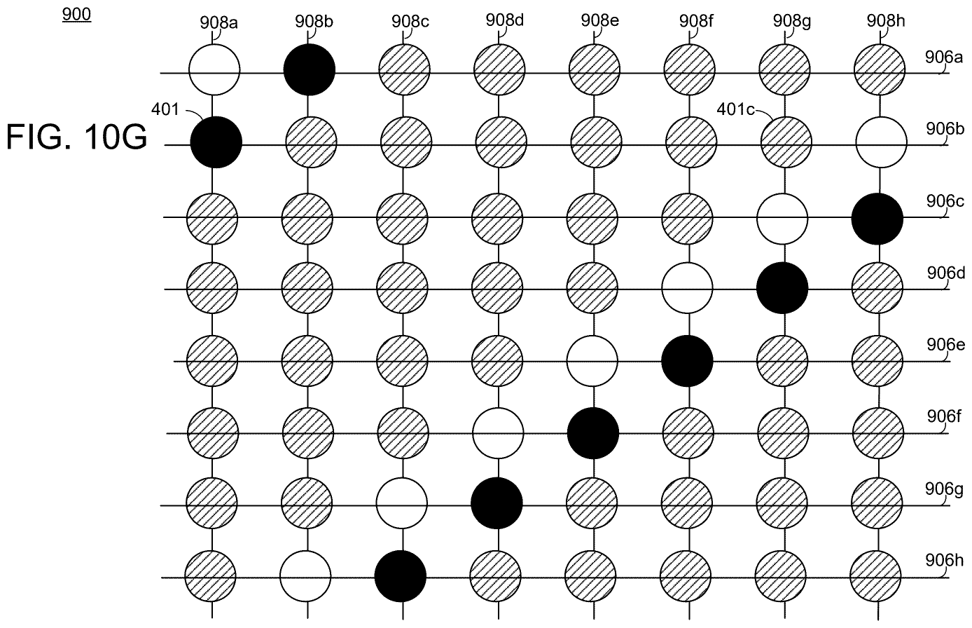

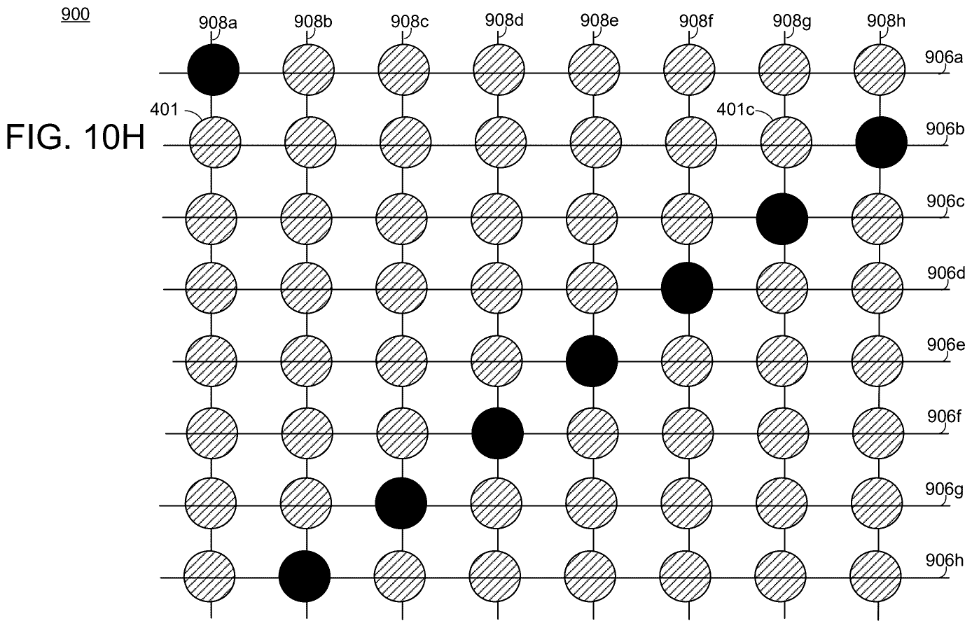

FIGS. 10A-10H depict a sequence of an embodiment of performing forming operations in a cross-point array. Referring now to FIG. 10A, an eight by eight portion of the cross-point array 900 is depicted. There are eight first conductive lines 906a, 906b, 906c, 906d, 906e, 906f, 906g, and 906h and eight second conductive lines 908a, 908b, 908c, 908d, 908e, 908f, 908g, and 908h. For convenience of explanation, the first conductive lines will be referred to as word lines sand the second conductive lines will be referred to as bit lines, although this terminology may be reversed. A memory cell 401 is depicted at that junction between each word line and bit line. Each memory cell 401 is connected between one of the word lines and one of the bit lines, as has been explained herein. The word lines are shown as being “closer” to the viewer (e.g., running above the memory cells) and the bit lines are shown as being “farther” from the viewer (e.g., running below the memory cells). The eight memory cells 401 in black are a group that has been identified for receiving a forming operation during a first time period. The forming operation may be applied to each of the eight memory cells 401 separately (e.g., at a different time in the first time period). The eight memory cells 401 will undergo the forming operation during a period of time in which no other memory cells in the array 900 will undergo a forming operation. Each memory cell 401 in this group is the only cell in the group connected to its word line and to its bit line. For example, the memory cell 401c connected to word line 906b and bit line 908g is the only memory cell in the group connected to word line 906b and the only memory cell in the group connected to bit line 908g. Also note that each word line is connected to only one memory cell in the group. Furthermore, each bit line is connected to only one memory cell in the group. Each word line is connected to at most one memory cell in the group and each bit line is connected to at most one memory cell in the group. In the example in FIG. 10A, the memory cells in the group are arranged in a diagonal across the array 900; however, a different pattern could be used. Also note that typically the cross-point array 900 will have many more memory cells 401 then in the example. Therefore, the first group of memory cells to undergo the forming operation will typically contain many more memory cells. For example, there may be one memory cell in the group for each word line with the array having more than 1000 word lines. As another example, there may be one memory cell in the group for each bit line with the array having more than 1000 bit lines.

The strategy for deciding which memory cells are in the group to receive forming operations reduces the likelihood that an unselected memory cell that is half selected will turn on. For example, when the memory cell 401c connected to word line 906b and bit line 908g is selected for the forming operation a forming voltage may be applied to word line 906b while bit line 908g is at 0 V. All other word lines and all other bit lines are unselected and may have a voltage of one half the forming voltage applied thereto. More generally, the forming voltage is applied across the selected memory cell 401c. In one biasing scheme, when the memory cell 401c connected to word line 906b and bit line 908g is selected for the forming operation +Vs/2 may be applied to word line 906b while bit line 908g is at −Vs/2 with all other word lines and all other bit lines at 0 V. The unselected memory cells connected to the selected word line 906b are “half-selected”. Also, the unselected memory cells connected to the selected bit line 908g are “half-selected”. Note that none of the half-selected memory cells are in the group that will undergo a forming operation in the present time period. This statement applies to all memory cells in the group. For example, none of memory cells that are half-selected when the memory cell 401a is selected are in the group that will undergo a forming operation in the present time period; none of memory cells that are half-selected when the memory cell 401d is selected are in the group that will undergo a forming operation in the present time period, etc.

After a forming operation has been applied to all of the memory cells in the first group, a second group of memory cells is identified for a forming operation. FIG. 10B depicts the cross-point memory array 900 of FIG. 10A, with a second group of memory cell 401 identified for a forming operation. The second group of memory cell 401 are depicted in black. For reference, the first group of memory cell 401 are depicted in cross-hatching. The memory cells in the second group follows the rule that each memory cell 401 in the second group is the only cell in the group connected to its word line and to its bit line. Also note that each word line is connected to only one memory cell in the second group. Furthermore, each bit line is connected to only one memory cell in the second group. Each word line is connected to at most one memory cell in the second group and each bit line is connected to at most one memory cell in the second group. The strategy for deciding which memory cells are in the second group reduces the likelihood that an unselected memory cell that is half selected will turn on. Note that some time will have passed since the memory cells in the first group received the forming operation. Therefore, the Vth of the memory cells in the first group may have relaxed somewhat. With reference to FIG. 8, at least some of the memory cells in the first group may now have their Vths on plot 806, such as point 812. Since their Vths have increased since the forming operation the likelihood of a half select event is reduced. Furthermore, note that when the Vth increases the leakage current of the cell decreases. Decreasing the leakage current will decrease the IR drop on the word line and/or bit line thereby resulting in more voltage across the selected memory cell.

The memory cells in the second group may be selected for the forming operation in an order that results in a target delay between the forming of the cells in the first group and cells in the second group (factoring in which cells in the first group are half-selected). For example, assume that the cells in the first group were formed starting at memory cell 401a, then proceeding diagonally to memory cell 401c, 401d, etc. Selecting memory cell 401e as the first cell in the second group results in a large delay (thereby meeting a target delay) since the forming of half-selected memory cells 401a and 401c. Thus, memory cells 401a and 401c should have a relaxed Vth such as on plot 806 in FIG. 8. Then, then forming may proceed diagonally to memory cell 401f, etc. Other orders may be used to achieve a target delay between the forming of half-selected memory cells in the first group and the presently selected cell in the second group. In general, the order results in a target delay between the forming operation of half-selected memory cells in the first group and the forming operation of corresponding selected memory cells in the second group.

After a forming operation has been applied to all of the memory cells in the second group during a second time period, a third group of memory cells is identified for a forming operation. FIG. 10C depicts the cross-point memory array 900 of FIG. 10A, with a third group of memory cell 401 identified for a forming operation. The third group of memory cell 401 are depicted in black. For reference, the first and second groups of memory cells 401 are depicted in cross-hatching. The memory cells in the third group follows the rule that each memory cell 401 in the third group is the only cell in the group connected to its word line and to its bit line. Also note that each word line is connected to only one memory cell in the third group. Furthermore, each bit line is connected to only one memory cell in the third group. Each word line is connected to at most one memory cell in the third group and each bit line is connected to at most one memory cell in the third group. The strategy for deciding which memory cells are in the third group reduces the likelihood that an unselected memory cell that is half selected will turn on.

After a forming operation has been applied to all of the memory cells in the third group during a third time period, a fourth group of memory cells is identified for a forming operation. FIG. 10D depicts the cross-point memory array 900 of FIG. 10A, with a fourth group of memory cell 401 identified for a forming operation. The fourth group of memory cell 401 are depicted in black. For reference, the first, second and third groups of memory cells 401 are depicted in cross-hatching. The memory cells in the fourth group follows the rule that each memory cell 401 in the fourth group is the only cell in the group connected to its word line and to its bit line. Also note that each word line is connected to only one memory cell in the fourth group. Furthermore, each bit line is connected to only one memory cell in the fourth group. Each word line is connected to at most one memory cell in the fourth group and each bit line is connected to at most one memory cell in the fourth group. The strategy for deciding which memory cells are in the fourth group reduces the likelihood that an unselected memory cell that is half selected will turn on.

After a forming operation has been applied to all of the memory cells in the fourth group during a fourth time period, a fifth group of memory cells is identified for a forming operation. FIG. 10E depicts the cross-point memory array 900 of FIG. 10A, with a fifth group of memory cell 401 identified for a forming operation. The fifth group of memory cell 401 are depicted in black. For reference, the first, second, third and fourth groups of memory cells 401 are depicted in cross-hatching. The memory cells in the fifth group follows the rule that each memory cell 401 in the fifth group is the only cell in the group connected to its word line and to its bit line. Also note that each word line is connected to only one memory cell in the fifth group. Furthermore, each bit line is connected to only one memory cell in the fifth group. Each word line is connected to at most one memory cell in the fifth group and each bit line is connected to at most one memory cell in the fifth group. The strategy for deciding which memory cells are in the fifth group reduces the likelihood that an unselected memory cell that is half selected will turn on.

After a forming operation has been applied to all of the memory cells in the fifth group during a fifth time period, a sixth group of memory cells is identified for a forming operation. FIG. 10F depicts the cross-point memory array 900 of FIG. 10A, with a sixth group of memory cell 401 identified for a forming operation. The sixth group of memory cell 401 are depicted in black. For reference, the first, second, third, fourth and fifth groups of memory cells 401 are depicted in cross-hatching. The memory cells in the sixth group follows the rule that each memory cell 401 in the sixth group is the only cell in the group connected to its word line and to its bit line. Also note that each word line is connected to only one memory cell in the sixth group. Furthermore, each bit line is connected to only one memory cell in the sixth group. Each word line is connected to at most one memory cell in the sixth group and each bit line is connected to at most one memory cell in the sixth group. The strategy for deciding which memory cells are in the sixth group reduces the likelihood that an unselected memory cell that is half selected will turn on.

After a forming operation has been applied to all of the memory cells in the sixth group during a sixth time period, a seventh group of memory cells is identified for a forming operation. FIG. 10G depicts the cross-point memory array 900 of FIG. 10A, with a seventh group of memory cell 401 identified for a forming operation. The seventh group of memory cell 401 are depicted in black. For reference, the first, second, third, fourth, fifth and sixth groups of memory cells 401 are depicted in cross-hatching. The memory cells in the seventh group follows the rule that each memory cell 401 in the seventh group is the only cell in the group connected to its word line and to its bit line. Also note that each word line is connected to only one memory cell in the seventh group. Furthermore, each bit line is connected to only one memory cell in the seventh group. Each word line is connected to at most one memory cell in the seventh group and each bit line is connected to at most one memory cell in the seventh group. The strategy for deciding which memory cells are in the seventh group reduces the likelihood that an unselected memory cell that is half selected will turn on.

After a forming operation has been applied to all of the memory cells in the seventh group during a seventh time period, an eighth group of memory cells is identified for a forming operation during an eighth time period. FIG. 10H depicts the cross-point memory array 900 of FIG. 10A, with an eighth group of memory cell 401 identified for a forming operation. The eighth group of memory cell 401 are depicted in black. For reference, the first, second, third, fourth, fifth, sixth and seventh groups of memory cells 401 are depicted in cross-hatching. The memory cells in the eighth group follows the rule that each memory cell 401 in the eighth group is the only cell in the group connected to its word line and to its bit line. Also note that each word line is connected to only one memory cell in the eighth group. Furthermore, each bit line is connected to only one memory cell in the eighth group. Each word line is connected to at most one memory cell in the eighth group and each bit line is connected to at most one memory cell in the eighth group. The strategy for deciding which memory cells are in the eighth group reduces the likelihood that an unselected memory cell that is half selected will turn on. After the forming operation has been applied to each of the eight groups, the process may be repeated again on the eight groups.

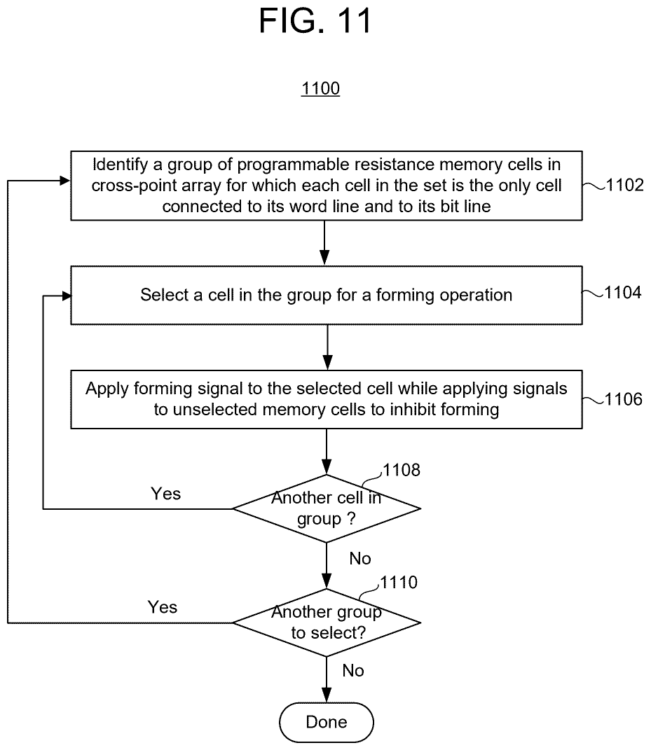

FIG. 11 is a flowchart of one embodiment of a process 1100 of performing forming operations in a cross-point array. The process 1100 could be performed at a fabrication facility, a test facility, or by a distributor prior to shipping the memory system and/or dies 202, 280 to a customer. In an embodiment, one or more control circuits in the memory system perform the process 1100 at least in part. In an embodiment, one or more control circuits external to the memory system (such as a test circuitry 103) perform the process 1100 at least in part. The process 1100 may be used to perform a forming operations on Ovonic Threshold Switches (OTS). Other types of threshold switching selectors may be formed by performing process 1200. In an embodiment, the threshold switching selector is in series with a programmable resistance memory element 702. Examples of the programmable resistance memory elements include, but are not limited to, MRAM, ReRam, PCM (Phase Change Memory, and FeRam.

Step 1102 includes identifying a group of programmable resistance memory cells in cross-point array for which each cell in the group is the only cell connected to its word line and to its bit line. Memory cells are included in the group to reduce the likelihood that an unselected memory cell that is half selected will turn on during a forming operation of a memory cell in the group. Example groups are depicted in FIGS. 10A-10H .

Step 1104 includes selecting a memory cell in the group for a forming operation. In an embodiment, the memory cell is selected to create a target delay between the prior forming of half-selected memory cells and the forming operation of the presently selected cell. This target delay allows the Vth of the prior formed memory cells to relax (e.g., increase) to thereby reduce the likelihood of an undesirable half-select event in the memory cell that previously underwent a forming operation.

Step 1106 includes applying a forming signal to the selected memory cell while applying signals to unselected memory cells to inhibit forming. Example voltages to apply to the word lines and bit lines are depicted in FIG. 9A when memory cell 401c is selected. As an alternative to applying Vs to the selected word line, a current may be applied to the selected word line. The current will charge up the voltage on the selected word line such that a voltage appears across the selected memory cell. In an alternative biasing scheme +Vs/2 is applied to the selected word line and −Vs/2 is applied to the selected bit line Step 1108 includes a determination of whether there are more memory cells in the group to receive a forming operation. If so, steps 1104 and 1106 are repeated until all memory cells in the group have received a forming operation. Therefore, the forming operation is applied to the group during a period of time. Then, in step 1110 a determination is made whether there is another group of memory cells in the cross-point array to receive a forming operation. If so, another group of memory cells is identified in step 1102. Then, the forming operations are performed on each memory cell in this new group (steps 1104 and 1106) as previously described for the first group. As has been described herein, the Vth of the selectors in the previous group will relax (e.g., increase) such that half-select events are significantly less likely. When all groups of memory cells have received the forming operation, the process ends.

In some embodiments, the process 1100 may then be repeated to perform additional forming operations on the memory cells. In one embodiment, each time that process 1100 is performed the threshold switching selectors in the memory cells are “partially formed”. For example, each time that process 1100 is performed the Vths of threshold switching selectors may be lowered part way to a target operating Vth. Therefore, the process 1100 may be performed a number of times to complete the forming of the memory cells.

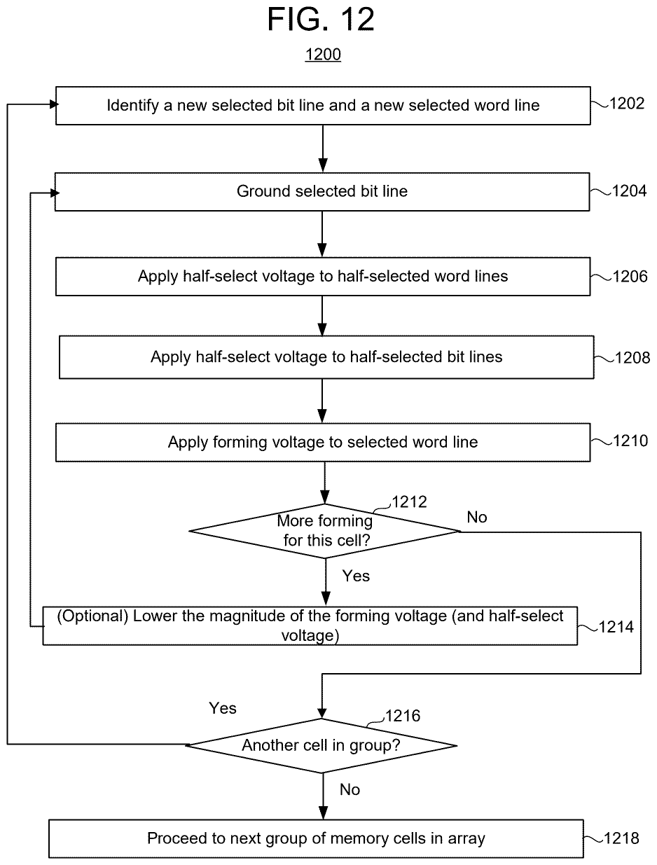

FIG. 12 is a flowchart of an embodiment of a process 1200 of performing forming operations in a cross-point memory array. Process 1200 provides further details of an embodiment of process 1100. The process 1200 may be used to perform a forming operations on Ovonic Threshold Switches (OTS). Other types of threshold switching selectors may be formed by performing process 1200. In an embodiment, the threshold switching selector is in series with a programmable resistance memory element 702. Examples of the programmable resistance memory elements include, but are not limited to, MRAM, ReRam, PCM (Phase Change Memory, and FeRam.

Step 1202 includes identifying a new selected bit line and a new selected word line. This identification made based on the memory cell that is selected for the forming operation. An example will be discussed in which the selected word line is word line 906b and the selected bit line is bit line 908g (see FIG. 10A). Process 1200 thus starts with an assumption that a first group of memory cells has been selected for a forming operation. Step 1202 may also include setting an initial magnitude for a forming voltage. In an embodiment, the initial magnitude for the forming voltage is greater than the largest expected initial threshold voltage (e.g., Vff) of the threshold switching selector. An example for the initial magnitude for the forming voltage is about 4.2 V, but this magnitude could be different depending the characteristics of the threshold switching selector.

Steps 1204-1210 are described in a certain order for convenience of explanation. Steps 1204-1210 may occur in a different order and/or some of these steps may be performed concurrently. Step 1204 includes grounding the selected bit line. For example, 0 V applied to bit line 908g. Step 1206 includes applying a half-select voltage Vs/2 to the half-selected word lines. For example, Vs/2 is applied to word lines 906a, 906c, 906d, 906e, 906f, 906g, and 906h. Step 1208 includes applying a half-select voltage Vs/2 to the half-selected bit lines. For example, Vs/2 is applied to bit lines 908a, 908b, 908c, 908d, 908e, 908f, and 908h. Step 1210 includes applying the forming voltage to the selected word line. For example, Vs is applied to word line 906b. An example range for the duration of the forming voltage is 10 nanoseconds (ns) to 100 ns. However, the duration of the forming voltage could be longer or shorter than this example range. In an embodiment, the forming voltage is applied to one end of the selected memory cell with the other end of the selected memory cell at ground.

Step 1212 includes a determination of whether to perform additional forming for this cell. In step 1212 the memory system could test the threshold voltage of the memory cell to determine whether the threshold voltage has reached a target level. An example range of the target level is between 2 V to 3 V, although the target level could be below or above this range. It is not required that the threshold voltage be tested each iteration. Rather, the memory system might apply the forming voltage a number of times between each test of the threshold voltage.

Step 1214 is performed in the event that more forming is to be performed for the presently selected memory cell. Step 1214 is the optional lowering of the forming voltage. In one embodiment, the memory system will apply the forming voltage to the selected memory cell at the present magnitude a pre-determined number of times. The memory system may change the polarity of the forming signal in the next application. For example, in one iteration of steps 1204-1210 the forming voltage may result in a positive voltage from word line to bit line and in another iteration of steps 1204-1210 the forming voltage may result in a negative voltage from word line to bit line. Step 1214 may include lowering the magnitude of the forming voltage. As an example, the magnitude of the forming voltage may be lowered by 100 mV. The magnitude of the half-select voltage is also lowered accordingly, such that the half-select voltage remains at Vs/2.

After it is determined that no more forming is to be performed for the presently selected memory cell control passes to step 1216. Step 1216 includes a determination of whether there are more memory cells in the group to receive the forming operation. Step 1204-1214 are performed for each memory cell in this group. When all memory cells in the group have received their forming operation(s) control passes to step 1218. Step 1218 is proceeding to the next group of memory cells in the cross-point array. For example, after apply the forming operations to the cell in the group in FIG. 10A, process 1200 may be applied to the cells in the group identified in FIG. 10B, then to the cells in the group identified in FIG. 10C etc. until all groups have received forming operations. As discussed above, after all groups have received formation operations of process 1200, the entire sequence can be performed again. That is, each group may again undergo forming operations of process 1200.

Process 1200 describes an example biasing scheme in which the forming voltage is applied to the selected word line. Another alternative is to apply Vs/2 to the selected word line with −Vs/2 to the selected bit line. Other biasing schemes may be used to apply the forming voltage across the selected memory cell.

Although numerous examples have been presented above in which the forming operation is applied lower the Vth of a threshold switching selector (e.g., OTS), the disclosed sequence for the forming operations in a cross-point array is not limited to threshold switching selector, but may be applied to other memory cells in a cross-point array that may benefit from a forming operation. In an embodiment, the sequence for the forming operations is applied to ReRAM cells a cross-point array. For example, the memory cells 401 in FIGS. 10A-10H could be ReRAM cells. Likewise, process 1100 could be applied to ReRAM cells a cross-point array.

In view of the foregoing, it can be seen that, according to an embodiment, an apparatus comprises a cross-point array comprising a plurality of first conductive lines, a plurality of second conductive lines, and programmable resistance memory cells. The apparatus comprises one or more control circuits in communication with the cross-point array. The one or more control circuits are configured to identify a first group of programmable resistance memory cells in the cross-point array for a forming operation. Each programmable resistance memory cell in the first group is connected between a first conductive line of the plurality of first conductive lines and a second conductive line of the plurality of second conductive lines that are not connected to any other memory cell in the first group. The one or more control circuits are configured to apply at least one forming signal to each programmable resistance memory cell in the first group during a first period of time in which no forming signal is applied to any other programmable resistance memory cell in the cross-point array.

In a further embodiment, the one or more control circuits are configured to: i) identify a second group of programmable resistance memory cells in the cross-point array for the forming operation after performing the forming operation on all memory cells in the first group. Each programmable resistance memory cell in the second group is connected between a first conductive line and a second conductive line that are not connected to any other memory cell in the second group. The one or more control circuits are configured to: ii) apply at least one forming signal to each programmable resistance memory cell in the second group during a second period of time in which no forming signal is applied to any other programmable resistance memory cell in the cross-point array. The one or more control circuits are configured to iii) repeat said i) and said ii) on a group-by-group basis during additional time periods until the forming operation has been performed on all memory cells in the cross-point array.

In a further embodiment, each first conductive line is connected to one memory cell in each group.

In a further embodiment, each second conductive line is connected to one memory cell in each group.

In a further embodiment, for each time period each memory cell in the group identified for the forming operation is either fully selected or fully unselected.

In a further embodiment, each group contains “n” memory cells. And the plurality of first conductive lines contains a corresponding “n” conductive lines.

In a further embodiment, the one or more control circuits are configured to apply the forming operation to the memory cells in the second group in an order that results in a target delay between the forming operation of half-selected memory cells in the first group and the forming operation of corresponding selected memory cells in the second group.

In a further embodiment, the forming operation lowers a threshold voltage of a threshold switch in each programmable resistance memory cell partially to a final target threshold voltage. The one or more control circuits are configured to repeat the forming operation for each group until the final target threshold voltage has been reached.

In a further embodiment, the memory cells in the first group are arranged in one or more diagonals across the cross-point array.

In a further embodiment, the one or more control circuits are configured to: i) select a memory cell in the first group for the forming operation; ii) apply at least one forming signal to the selected memory cell in the first group while applying signals to unselected memory cells in the cross-point array to inhibit forming; and iii) repeat said i) and said ii) for all memory cells in the first group prior to applying the forming operation to another group of programmable resistance memory cells in the cross-point array.

In a further embodiment, the programmable resistance memory cells each comprise a threshold switching selector in series with a programmable resistance memory element. And the one or more control circuits perform the forming operation to lower threshold voltages of the threshold switching selectors.

In a further embodiment, the programmable resistance memory cells each comprise an Ovonic Threshold Switch (OTS) memory element. And the forming operation is performed to lower threshold voltages of each OTS.

In a further embodiment, the programmable resistance memory cells each comprise a ReRAM memory cell. And the one or more control circuits perform the forming operation to form conductive pathways in the ReRAM memory cell.

An embodiment includes a method for performing a forming operation in programmable resistance memory cells in a cross-point array having a plurality of word lines and a plurality of bit lines. The method comprises: a) identifying a group of the programmable resistance memory cells in the cross-point array for which each memory cell in the group is the only memory cell connected to its word line and to its bit line. The programmable resistance memory cell includes a threshold switching device having a threshold voltage at which the threshold switching device turns on. The method comprises: b) selecting a memory cell in the identified group for the forming operation; c) applying a forming signal to the selected memory cell to lower the threshold voltage of the threshold switching device while applying signals to unselected memory cells in the array to inhibit turning on the threshold switching device in the unselected memory cells; d) repeating said b) and said c) until the forming operation has been applied to all memory cells in the identified group; and e) repeating said a) through said d) on a group-by-group basis until the forming operation has been performed on all memory cells in the cross-point array, wherein for each group each memory cell in the group is the only memory cell connected to its word line and to its bit line.

An embodiment includes a system comprising a cross-point array comprising a plurality of first conductive lines, a plurality of second conductive lines, and programmable resistance memory cells. Each programmable resistance memory cell is connected between one of the first conductive lines and one of the second conductive lines. Each programmable resistance memory cell has a threshold switch having a threshold voltage at which the threshold switch turns on. The system comprises one or more control circuits in communication with the cross-point array. The one or more control circuits are configured to: a) identify a group of the programmable resistance memory cells in the cross-point array for a forming operation, the group contains a memory cell connected to each of the first conductive lines; b) select a memory cell in the identified group for the forming operation; c) apply a forming voltage to the selected memory cell to lower a threshold voltage of the threshold switch while applying voltages to unelected memory cell in the cross-point array to inhibit turning on the threshold switches in the unelected memory cells, wherein all unselected memory cells in the group are fully unselected; d) repeat said b) and said c) during a period of time until the forming operation has been applied to all memory cells in the identified group; and e) repeat said a) through said d) on a group-by-group basis during other periods of time until the forming operation has been performed on all memory cells in the cross-point array.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable tolerance for a given application.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a cross-point array comprising a plurality of first conductive lines, a plurality of second conductive lines, and programmable resistance memory cells; and
one or more control circuits in communication with the cross-point array, wherein the one or more control circuits are configured to:
identify a first group of programmable resistance memory cells in the cross-point array for a forming operation, wherein each programmable resistance memory cell in the first group is connected between a first conductive line of the plurality of first conductive lines and a second conductive line of the plurality of second conductive lines that are not connected to any other memory cell in the first group; and
apply at least one forming signal to each programmable resistance memory cell in the first group during a first period of time in which no forming signal is applied to any other programmable resistance memory cell in the cross-point array.

2. The apparatus of claim 1, wherein the one or more control circuits are configured to:
i) identify a second group of programmable resistance memory cells in the cross-point array for the forming operation after performing the forming operation on all memory cells in the first group, wherein each programmable resistance memory cell in the second group is connected between a first conductive line and a second conductive line that are not connected to any other memory cell in the second group;
ii) apply at least one forming signal to each programmable resistance memory cell in the second group during a second period of time in which no forming signal is applied to any other programmable resistance memory cell in the cross-point array; and
iii) repeat said i) and said ii) on a group-by-group basis during additional time periods until the forming operation has been performed on all memory cells in the cross-point array.

3. The apparatus of claim 2, wherein each first conductive line is connected to one memory cell in each group.

4. The apparatus of claim 3, wherein for each time period each memory cell in the group identified for the forming operation is either fully selected or fully unselected.

5. The apparatus of claim 2, wherein:
each group contains “n” memory cells; and
the plurality of first conductive lines contains a corresponding “n” conductive lines.

6. The apparatus of claim 2, wherein the one or more control circuits are configured to apply the forming operation to the memory cells in the second group in an order that results in a target delay between the forming operation of half-selected memory cells in the first group and the forming operation of corresponding selected memory cells in the second group.

7. The apparatus of claim 2, wherein:
the forming operation lowers a threshold voltage of a threshold switch in each programmable resistance memory cell partially to a final target threshold voltage; and
the one or more control circuits are configured to repeat the forming operation for each group until the final target threshold voltage has been reached.

8. The apparatus of claim 1, wherein the memory cells in the first group are arranged in one or more diagonals across the cross-point array.

9. The apparatus of claim 1, wherein the one or more control circuits are configured to:
i) select a memory cell in the first group for the forming operation;
ii) apply at least one forming signal to the selected memory cell in the first group while applying signals to unselected memory cells in the cross-point array to inhibit forming; and
iii) repeat said i) and said ii) for all memory cells in the first group prior to applying the forming operation to another group of programmable resistance memory cells in the cross-point array.

10. The apparatus of claim 1, wherein:
the programmable resistance memory cells each comprise a threshold switching selector in series with a programmable resistance memory element; and
the one or more control circuits perform the forming operation to lower threshold voltages of the threshold switching selectors.

11. The apparatus of claim 10, wherein the programmable resistance memory cells each comprise an Ovonic Threshold Switch (OTS) memory element; and
the forming operation is performed to lower threshold voltages of each OTS.

12. The apparatus of claim 1, wherein:
the programmable resistance memory cells each comprise a ReRAM memory cell; and
the one or more control circuits perform the forming operation to form conductive pathways in the ReRAM memory cell.

13. A method for performing a forming operation in programmable resistance memory cells in a cross-point array having a plurality of word lines and a plurality of bit lines, the method comprising:
a) identifying a group of the programmable resistance memory cells in the cross-point array for which each memory cell in the group is the only memory cell connected to its word line and to its bit line, wherein each programmable resistance memory cell includes a threshold switching device having a threshold voltage at which the threshold switching device turns on;
b) selecting a memory cell in the identified group for the forming operation;
c) applying a forming signal to the selected memory cell to lower the threshold voltage of the threshold switching device while applying signals to unselected memory cells in the array to inhibit turning on the threshold switching device in the unselected memory cells;
d) repeating said b) and said c) until the forming operation has been applied to all memory cells in the identified group; and
e) repeating said a) through said d) on a group-by-group basis until the forming operation has been performed on all memory cells in the cross-point array, wherein for each group each memory cell in the group is the only memory cell connected to its word line and to its bit line.

14. The method of claim 13, wherein identifying the group of the programmable resistance memory cells in the cross-point array for which each memory cell in the group is the only memory cell connected to its word line and to its bit line comprises:
identifying a programmable resistance memory cell for each word line of the plurality of word lines.

15. The method of claim 13, wherein identifying the group of the programmable resistance memory cells in the cross-point array for which each memory cell in the group is the only memory cell connected to its word line and to its bit line comprises:
identifying a programmable resistance memory cell for each bit line of the plurality of word lines.

16. The method of claim 13, wherein identifying the group of the programmable resistance memory cells in the cross-point array for which each memory cell in the group is the only memory cell connected to its word line and to its bit line comprises:
identifying programmable resistance memory cell that are arranged in one or more diagonals across the cross-point array.

17. A system, comprising:
a cross-point array comprising a plurality of first conductive lines, a plurality of second conductive lines, and programmable resistance memory cells, each programmable resistance memory cell connected between one of the first conductive lines and one of the second conductive lines, each programmable resistance memory cell having a threshold switch having a threshold voltage at which the threshold switch turns on; and
one or more control circuits in communication with the cross-point array, wherein the one or more control circuits are configured to:
a) identify a group of the programmable resistance memory cells in the cross-point array for a forming operation, the group contain a memory cell connected to each of the first conductive lines;
b) select a memory cell in the identified group for the forming operation;
c) apply a forming voltage to the selected memory cell to lower a threshold voltage of the threshold switch while applying voltages to unelected memory cell in the cross-point array to inhibit turning on the threshold switches in the unelected memory cells, wherein all unselected memory cells in the group are fully unselected;
d) repeat said b) and said c) during a period of time until the forming operation has been applied to all memory cells in the identified group; and
e) repeat said a) through said d) on a group-by-group basis during other periods of time until the forming operation has been performed on all memory cells in the cross-point array.

18. The system of claim 17, wherein each programmable resistance memory cell comprises a programmable resistance memory element in series with the threshold switch, the threshold switch is a selector.

19. The system of claim 17, wherein the one or more one or more control circuits are configured to program the threshold switch in each of the programmable resistance memory cells as a resistance memory element.

20. The system of claim 17, wherein the threshold switch in each of the programmable resistance memory cells comprises an Ovonic Threshold Switch (OTS).
